(19) United States
(12) Patent Application Publication
(10) Pub. No.: US 2024/0421277 A1
(43) Pub. Date: Dec. 19, 2024

(54) PIXEL STRUCTURE AND DISPLAY DEVICE USING THE SAME

(71) Applicant: EPISTAR CORPORATION, Hsinchu (TW)

(72) Inventors: Min-Hsun HSIEH, Hsinchu (TW); Ying-Yang SU, Hsinchu (TW); Chien-Chih CHEN, Hsinchu (TW); Wei-Shan HU, Hsinchu City (TW); Ching-Tai CHENG, Hsinchu (TW); Chung-Che TENG, Hsinchu (TW); Tai-Ni CHU, Hsinchu (TW); Hsin-Mao LIU, Hsinchu City (TW)

(21) Appl. No.: 18/741,956

(22) Filed: Jun. 13, 2024

(30) Foreign Application Priority Data
Jun. 16, 2023 (TW) 112122762
Apr. 1, 2024 (TW) 113112331

(51) Int. Cl. H01L 33/62; H01L 25/075

(52) U.S. Cl. CPC H01L 33/62; H01L 25/0753

(57) ABSTRACT

A pixel structure includes a first light-emitting diode for emitting a first light, wherein the first light-emitting diode has a first semiconductor layer, a first light-emitting surface, and a first electrode under the first semiconductor layer away from the first light-emitting surface; a second light-emitting diode for emitting a second light, wherein the second light-emitting diode has a second semiconductor layer, a second light-emitting surface, and a second electrode under the second semiconductor layer away from the second light-emitting surface; a dielectric layer surrounding and contacting the first semiconductor layer and the second light-emitting diode and exposing the first light-emitting surface, the first electrode, the second light-emitting surface and the second electrode; a common conductive structure having a semiconductor layer and a metal layer; and a light-transmitting conductive layer covering and electrical connecting the first light-emitting diode, the second light-emitting diode and the common conductive structure.

### TECHNICAL FIELD

The present disclosure relates to a pixel structure, and in particular to a pixel structure with vertical red, blue, and green light-emitting diodes and a display device thereof.

### BACKGROUND

Light-Emitting Diode (LED) is a monochromatic light semiconductor element. When LEDs are used for pixels in a display device, each pixel includes at least one group of red, blue, and green LEDs. There are three structure types of LEDs: vertical type LED, horizontal type LED, and flip-chip type LED, wherein the p and n electrodes of the horizontal type and the flip-chip type LEDs are placed on the same side of the light-emitting layer, and the p and n electrodes of the vertical type LED are located on opposite sides of the light-emitting layer. Compared with the horizontal type and the flip-chip type LEDs, the vertical type LED produces similar luminous intensity with smaller size. Thus, the vertical type LED is more suitable for applied to the display device with high pixel density.

### CONTENTS OF INVENTION

A pixel structure includes a first light-emitting diode, a second light-emitting diode, a dielectric layer, a common conductive structure, and a light-transmissive conductive layer. The first light-emitting diode is used for emitting a first light, and has a first semiconductor layer, a first light-emitting surface, and a first electrode, wherein the first light-emitting surface and the first electrode are located on opposite sides of the first semiconductor layer. The second light-emitting diode is used for emitting a second light, and has a second semiconductor layer, a second light-emitting surface, and a second electrode, wherein the second light-emitting surface and the second electrode are located on opposite sides of the second semiconductor layer. The dielectric layer surrounds and contacts the first light-emitting diode and the second light-emitting diode and exposes the first light-emitting surface, the first electrode, the second light-emitting surface, and the second electrode. The common conductive structure has a semiconductor layer and a metal layer. The light-transmissive conductive layer covers and electrical connects the first light-emitting diode, the second light-emitting diode, and the common conductive structure.

### BRIEF DESCRIPTION OF THE DRAWINGS

FIG. 1 shows a cross-sectional view of a pixel structure according to an embodiment.

FIG. 2 shows a schematic structural diagram of a display device according to an embodiment.

FIG. 3A shows a top view of a pixel structure according to an embodiment.

FIG. 3B shows a top view of a pixel structure according to an embodiment.

FIG. 4 shows a schematic structural diagram of a first chip, a second chip, and a third chip according to an embodiment.

FIG. 5A shows a schematic structural diagram of a first chip, a second chip, and a third chip according to an embodiment.

FIG. 5B shows a top view of a common conductive structure, a first chip, a second chip, and a third chip according to an embodiment.

FIG. 6 shows a cross-sectional view of a pixel structure according to an embodiment.

FIGS. 7 to 11 show a manufacturing process of a pixel structure according to an embodiment.

FIG. 12 shows a cross-sectional view of a pixel structure according to an embodiment.

FIG. 13 shows a top view of a pixel structure according to an embodiment.

FIG. 14 shows a bottom view of a pixel structure according to an embodiment.

FIGS. 15 to 18 show a manufacturing process of a pixel structure according to an embodiment.

FIGS. 19 to 21 show a manufacturing process of a pixel structure according to another embodiment.

FIG. 22A shows a cross-sectional view of a chip according to an embodiment.

FIG. 22B shows an enlarged view of area G in FIG. 22A.

FIG. 23 shows a cross-sectional view of a chip according to an embodiment.

FIG. 24 shows a cross-sectional view of an arrangement structure according to an embodiment.

FIG. 25 shows a cross-sectional view of an arrangement structure according to another embodiment.

FIGS. 26 to 29 show a manufacturing process of an arrangement structure according to an embodiment.

FIG. 30 shows a cross-sectional view of an arrangement structure according to an embodiment.

FIG. 31 shows steps S200 to S208 of forming an arrangement structure C according to an embodiment.

FIG. 32A shows a cross-sectional view of a chip according to an embodiment.

FIG. 32B shows a cross-sectional view of a chip according to an embodiment.

FIGS. 33A to 33H show a manufacturing process of a chip according to an embodiment.

FIGS. 34A to 34C show multiple schematic structural diagrams of a display device according to an embodiment.

FIG. 35 shows a cross-sectional view of a chip temporarily fixed to a temporary carrier using an adhesive layer according to one embodiment.

FIG. 36 shows a cross-sectional view of a display device according to an embodiment.

FIG. 37 shows a schematic structural diagram of a light-emitting array device according to an embodiment.

FIG. 38A shows a cross-sectional view of a light-emitting array device according to an embodiment.

FIG. 38B shows a cross-sectional view of a light-emitting array device according to an embodiment.

FIG. 38C shows a top view of a light-emitting array device according to an embodiment.

FIGS. 39A to 39E show a manufacturing process of a light-emitting array device according to an embodiment.

FIGS. 40A to 40E show a manufacturing process of a light-emitting array device according to an embodiment.

### DETAILED DESCRIPTION

The following disclosure provides many different embodiments, or examples, for implementing different features of the provided quantum dot composite structures. Specific examples of components and arrangements are described below to simplify the present disclosure. These are, of course, merely examples and are not intended to be limiting. The disclosure may repeat symbols and/or characters of components in different embodiments or examples. This repetition is for simplicity and clarity, rather than to represent the relationship between the different embodiments and/or examples discussed.

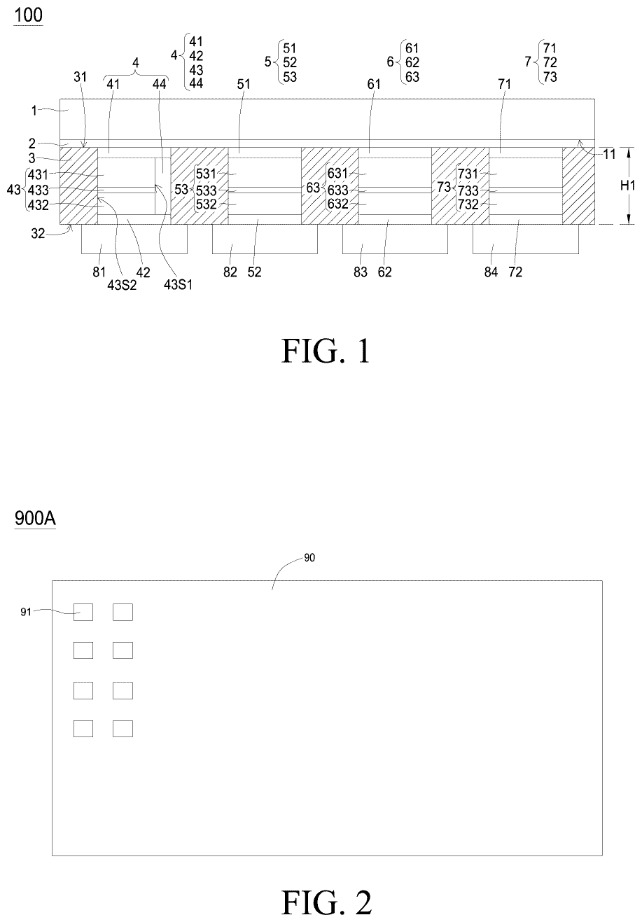

FIG. 1 shows a cross-sectional view of a pixel structure 100 according to an embodiment. The pixel structure 100 is able to emit red, blue, and green light and serves as a pixel of a display device. FIG. 2 shows a schematic structural diagram of a display device 900A. The display device 900A has a circuit board 90 and a plurality of pixels 91. The plurality of pixels 91 is arranged in an array on the circuit board 90, wherein the circuit board 90 can be a Printed Circuit Board (PCB) or a glass circuit board, and each of the plurality of pixels 91 can be the pixel structure 100 shown in FIG. 1.

As shown in FIG. 1, the pixel structure 100 has a light-transmissive carrier 1, a light-transmissive conductive layer 2, a common conductive structure 4, a dielectric layer 3, a first chip 5, a second chip 6, a third chip 7, a common bonding pad 81, a first bonding pad 82, a second bonding pad 83, and a third bonding pad 84. The light-transmissive conductive layer 2 is located below the light-transmissive carrier 1 and covers a surface 11 of the light-transmissive carrier 1. The common bonding pad 81, the first bonding pad 82, the second bonding pad 83, and the third bonding pad 84 can be used to connect external circuits (not shown). The common conductive structure 4 is located between the light-transmissive carrier 1 and the common bonding pad 81, and is connected to the light-transmissive conductive layer 2 and the common bonding pad 81 to conduct current between the light-transmissive conductive layer 2 and the common bonding pad 81. The first chip 5 is located between the light-transmissive carrier 1 and the first bonding pad 82 and is electrically connected to the light-transmissive conductive layer 2 and the first bonding pad 82. The second chip 6 is located between the light-transmissive carrier 1 and the second bonding pad 83 and is electrically connected to the light-transmissive conductive layer 2 and the second bonding pad 83. The third chip 7 is located between the light-transmissive carrier 1 and the third bonding pad 84 and is electrically connected to the light-transmissive conductive layer 2 and the third bonding pad 84. The first chip 5 can be driven to emit a first light, the second chip 6 can be driven to emit a second light, and the third chip 7 can be driven to emit a third light, wherein the first light, the second light, and the third light can be visible lights having the same or different wavelength ranges from each other, or invisible lights having the same or different wavelength ranges from each other. In order to isolate mechanical impact from an external environment and to improve the reliability of the pixel structure 100, the dielectric layer 3 surrounds the common conductive structure 4, the first chip 5, the second chip 6, and the third chip 7 from the sides and is connected to the light-transmissive conductive layer 2 directly or indirectly (not shown). In one embodiment, the dielectric layer 3, the common conductive structure 4, the first chip 5, the second chip 6, and the third chip 7 together form a first common surface 31 and a second common surface 32 that are opposite to each other. The first common surface 31 is in direct contact with the light-transmissive conductive layer 2, wherein the first common surface 31 and/or the second common surface 32 can be a flat surface or an uneven surface. The common bonding pad 81 locates below the second common surface 32 and is electrically connected to the common conductive structure 4. The first bonding pad 82 locates below the second common surface 32 and is electrically connected to the first chip 5. The second bonding pad 83 locates below the second common surface 32 and is electrically connected to the second chip 6. The third bonding pad 84 locates below the second common surface 32 and is electrically connected to the third chip 7. The pixel structure 100 can be connected to an external circuit (not shown) through the common bonding pad 81, the first bonding pad 82, the second bonding pad 83, and the third bonding pad 84 to receive power and be controlled to emit the first light, the second light and third light with specific brightness.

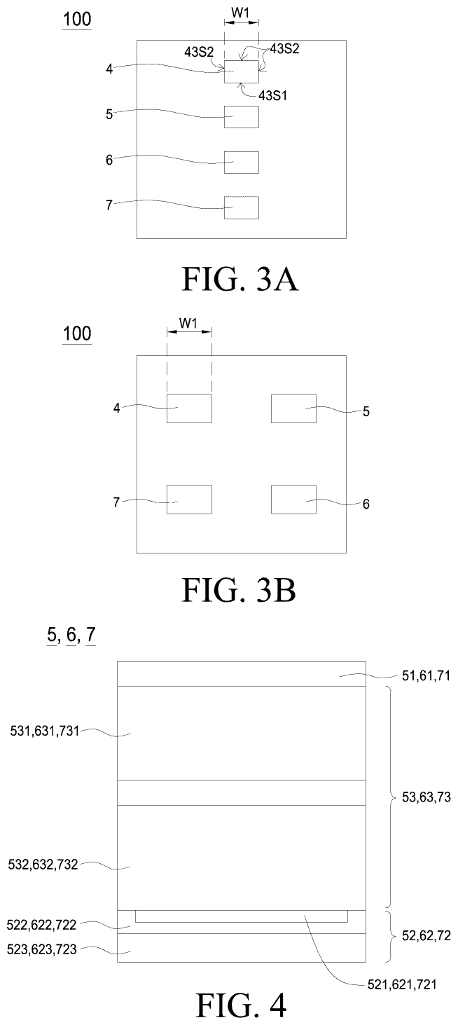

A top view of the pixel structure 100 as shown in FIG. 3A, the common conductive structure 4, the first chip 5, the second chip 6, and the third chip 7 are arranged in a line. In another embodiment, a top view of the pixel structure 100 as shown in FIG. 3B, wherein the common conductive structure 4, the first chip 5, the second chip 6, and the third chip 7 are arranged in an array. In other embodiments, orders or positions of the common conductive structure 4, the first chip 5, the second chip 6, and the third chip 7 can be adjusted according to the requirements. For example, the common conductive structure 4, the first chip 5, the second chip 6, and the third chip 7 can be arranged in a triangle, rhombus, or parallelogram.

As shown in FIG. 1, the common conductive structure 4 includes a semiconductor structure 43, an top electrode 41, a bottom electrode 42, and a conductive portion 44. The top electrode 41 is located above the semiconductor structure 43, and the bottom electrode 42 is located below the semiconductor structure 43. In one embodiment, as shown in FIG. 1 and FIG. 3A, the semiconductor structure 43 has a first sidewall 43S1 and a plurality of second sidewalls 43S2 located between the top electrode 41 and the bottom electrode 42. The conductive portion 44 covers and contacts the first sidewall 43S1 of the semiconductor structure 43, and is located between and directly connected to the top electrode 41 and the bottom electrode 42, wherein the plurality of second sidewalls 43S2 is not covered by the conductive portion 44. The semiconductor structure 43 includes an upper semiconductor layer 431, a lower semiconductor layer 432, and a multiple quantum well (MQW) structure 433 located between the upper semiconductor layer 431 and the lower semiconductor layer 432. The upper semiconductor layer 431 is electrically connected to the top electrode 41, and the lower semiconductor layer 432 is electrically connected to the bottom electrode 42. In one embodiment, all surfaces of the upper semiconductor layer 431, the MQW structure 433 and the lower semiconductor layer 432 compose the first sidewall 43S1 and in contact with the conductive portion 44, and the conductive portion 44 is made of a material with a resistance lower than that of the semiconductor structure 43. The material of the conductive portion 44 comprises a metal material, such as copper, tin, aluminum, silver, palladium, gold, alloys of the above materials, or laminates of the above materials. The current flows through the conductive portion 44 but not through the MQW structure 433, so the common conductive structure 4 is unable to emit light. In one embodiment, the conductive portion 44 covers and contacts the entire surface of the lower semiconductor layer 432 and the MQW structure 433 and a partial surface of the upper semiconductor layer 431 (not shown) on the first sidewall 43S1 of the semiconductor structure 43, so the conductive portion 44 is directly in contact with the bottom electrode 42 but not in contact with the top electrode 41. In one embodiment, a path of the current flowing between the top electrode 41 and the bottom electrode 42 is from the top electrode 41, passing through portion of the upper semiconductor layer 431 and the conductive portion 44, and then entering into the bottom electrode 42. In one embodiment, at the first sidewall 43S1 of the semiconductor structure 43, the conductive portion 44 covers and contacts the entire surfaces of the upper semiconductor layer 431 and the MQW structure 433 and a partial surface of the lower semiconductor layer 432 (not shown), so the conductive portion 44 is directly in contact with the top electrode 41 but not in contact with the bottom electrode 42. In one embodiment, a path of the current flowing between the top electrode 41 and the bottom electrode 42 is from the top electrode 41, passing through the conductive portion 44 and a portion of the lower semiconductor layer 432, and then entering into the bottom electrode 42. In one embodiment, at the first sidewall 43S1 of the semiconductor structure 43, the conductive portion 44 covers and contacts the entire surface of the MQW structure 433, the partial surfaces of the upper semiconductor layer 431 and the lower semiconductor layer 432 (not shown), so the conductive portion 44 is not in contact with the top electrode 41 and the bottom electrode 42. A path of the current flowing between the top electrode 41 and the bottom electrode 42 is from the top electrode 41, passing through portion of the upper semiconductor layer 431, the conductive portion 44, portion of the lower semiconductor layer 432, and then entering into the bottom electrode 42. In one embodiment, the conductive portion 44 covers the first sidewall 43S1 of the semiconductor structure 43 and a part of or the entire surface of the second sidewalls 43S2. That is, referring to FIG. 3A, the conductive portion 44 covers the entire or a partial surface of the sidewalls of the semiconductor structure 43 (not shown).

As shown in FIG. 1, the first chip 5 includes a first semiconductor stack 53, an upper electrode 51, and a lower electrode 52, wherein the upper electrode 51 is located above the first semiconductor stack 53, and the lower electrode 52 is located below the first semiconductor stack 53. The first semiconductor stack 53 includes a first upper semiconductor layer 531 electrically connected to the upper electrode 51, a first lower semiconductor layer 532 electrically connected to the lower electrode 52, and a first light-emitting layer 533 located between the first upper semiconductor layer 531 and the first lower semiconductor layer 532. The first light-emitting layer 533 is able to emit the first light when the current flows into the first semiconductor stack 53 through the upper electrode 51 or the lower electrode 52. The second chip 6 includes a second semiconductor stack 63, an upper electrode 61 and a lower electrode 62. The upper electrode 61 is located above the second semiconductor stack 63, and the lower electrode 62 is located below the second semiconductor stack 63. The second semiconductor stack 63 includes a second upper semiconductor layer 631 electrically connected to the upper electrode 61, a second lower semiconductor layer 632 electrically connected to the lower electrode 62, and a second light-emitting layer 633 located between the second upper semiconductor layer 631 and the second upper semiconductor layer 631. The second light-emitting layer 633 is able to emit the second light when the current flows into the second semiconductor stack 63 through the upper electrode 61 or the lower electrode 62. The third chip 7 includes a third semiconductor stack 73, an upper electrode 71 and a lower electrode 72. The upper electrode 71 is located above the third semiconductor stack 73, and the lower electrode 72 is located below the third semiconductor stack 73. The third semiconductor stack 73 includes a third upper semiconductor layer 731 electrically connected to the upper electrode 71, a third lower semiconductor layer 732 electrically connected to the lower electrode 72, and a third light-emitting layer 733 located between the third upper semiconductor layer 731 and the third lower semiconductor layer 732. The third light-emitting layer 733 is able to emit the third light when the current flows into the third semiconductor stack 73 through the upper electrode 71 or the lower electrode 72. In one embodiment, the first chip 5 is a blue light-emitting diode that can emit blue light (first light) with a dominant wavelength or a peak wavelength between 440 nm and 480 nm, the second chip 6 is a green light-emitting diode that can emit green light (second light) with a dominant wavelength or a peak wavelength between 500 nm and 540 nm, and the third chip 7 is a red light-emitting diode that can emit red light (third light) with a dominant wavelength or peak wavelength between 600 nm and 660 nm. The semiconductor stacks of blue light-emitting diode and green light-emitting diode include gallium nitride (GaN) series of semiconductor, and the semiconductor stack of red light-emitting diode includes aluminum gallium indium phosphide (AlGaInP) series of semiconductor. In one embodiment, the first chip 5 is a green light-emitting diode, the second chip 6 is a red light-emitting diode, and the third chip 7 is a blue light-emitting diode. In another embodiment, the first chip 5 is a red light-emitting diode, the second chip 6 is a blue light-emitting diode, and the third chip 7 is a green light-emitting diode.

In one embodiment, the semiconductor structure 43 has the same or similar structure as one of the first semiconductor stack 53, the second semiconductor stack 63, and the third semiconductor stack 73. The top electrode 41 has the same or similar structure as one of the upper electrodes 51, 61 and 71. The bottom electrode 42 has the same or similar structure as one of the lower electrodes 52, 62 and 72. The difference between the common conductive structure 4 and all of the first chip 5, the second chip 6, and the third chip 7 is that the common conductive structure 4 has a conductive portion 44 covering the first sidewall 43S1 and/or the second sidewalls 43S2 of the semiconductor structure 43. Therefore, the common conductive structure 4 provides a current path between the common bonding pad 81 and the light-transmissive conductive layer 2 and is unable to emit light. In the conventional packaging technology, a conductive pillar is usually used for conducting current between different conductive layers, and the material of the conductive pillar is selected from metals, such as copper and gold. The conductive pillar is usually manufactured by an electroplating process, which is usually expensive and time-consuming. In one embodiment, the common conductive structure 4 is disposed between the light-transmissive conductive layer 2 and the common bonding pad 81 for conducting the current. The structure and manufacturing process of the common conductive structure 4 is similar to those of the first chip 5, the second chip 6, or the third chip 7, so that the common conductive structure 4 can be mass-produced together with the first chip 5, the second chip 6, or the third chip 7. Since the conductive pillars can be omitted, the cost and the manufacturing process of forming the pixel structure 100 shown in FIG. 1 can be reduced.

As shown in FIG. 1, the common conductive structure 4, the first chip 5, the second chip 6, and the third chip 7 have same height H1. In one embodiment, the height H1 is less than 100 μm, or between 1 μm and 10 μm. FIGS. 3A and 3B show a top view of the pixel structure 100. As shown in FIGS. 3A and 3B, the outer contours of the common conductive structure 4, the first chip 5, the second chip 6, and the third chip 7 are all rectangular with a side length W1. In one embodiment, the side length W1 is between 1 μm and 100 μm.

As shown in FIG. 1, in one embodiment, the first upper semiconductor layer 531, the second upper semiconductor layer 631, and the third upper semiconductor layer 731 include a p-type semiconductor layer. The first lower semiconductor layer 532, the second lower semiconductor layer 632, and the third lower semiconductor layer 732 include a n-type semiconductor layer. The upper electrode 51, the upper electrode 61, and the upper electrode 71 include light-transmitting conductive material, and the contact resistance with the p-type semiconductor layer is less than 10⁻² Ω·cm. The light-transmitting conductive material includes Indium Tin Oxide (ITO), which has a transmittance more than 80% for visible light with a main wavelength or peak wavelength between 440 nm and 660 nm. The lower electrode 52, the lower electrode 62, and the lower electrode 72 have the same or similar metal laminate structure. FIG. 4 shows a schematic structural diagram of the first chip 5, the second chip 6, and the third chip 7. As shown in FIG. 4, the lower electrode 52, 62, 72 includes a reflective metal layer 521, 621, 721 connected to the lower semiconductor layer 532, 632, 732 for reflecting the first light, the second light, or the third light. A barrier metal layer 522, 622, 722 covers the reflective metal layer 521, 621, 721 to prevent the reflective metal layer 521, 621, 721 from metal ion migration during the current flowing through the first chip 5, the second chip 6, or the third chip 7. A metal connection layer 523, 623, 723 covers the barrier metal layer 522, 622, 722 and connect with the first bonding pad 82, the second bonding pad 83, or the third bonding pad 84. The reflective metal layer 521, 621, 721 includes metals with a reflectivity greater than 80% for the first light, the second light, or the third light, such as aluminum (Al) or silver (Ag). The barrier metal layer 522, 622, 722 includes titanium (Ti), platinum (Pt), titanium (Ti), platinum (Pt) or a stack thereof. The metal connection layer 523, 623, 723 includes gold (Au).

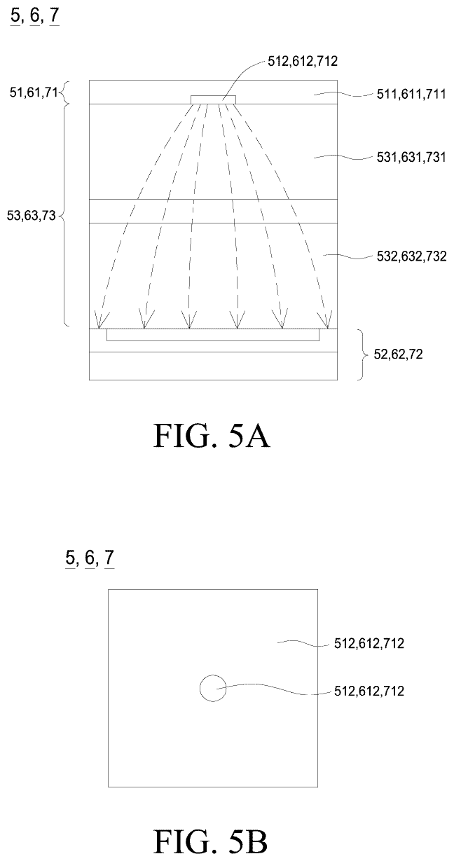

In one embodiment, FIG. 5A shows a schematic structural diagram of the first chip 5, the second chip 6, and the third chip 7. The first upper semiconductor layer 531, the second upper semiconductor layer 631, and the third upper semiconductor layer 731 include an n-type semiconductor layer, and the first lower semiconductor layer 532, the second lower semiconductor layer 632, and the third lower semiconductor layer 732 include a p-type semiconductor layer. The upper electrode 51 includes a light-transmissive conductive layer 511 for covering the upper semiconductor layer 531, the upper electrode 61 includes a light-transmissive conductive layer 611 for covering the upper semiconductor layer 631, and the upper electrode 71 includes a light-transmissive conductive layer 711 for covering the upper semiconductor layer 731, wherein the upper semiconductor layers 531, 631, 731 include the n-type semiconductor layer. A current channel layer 512, 612, 712 is located between the upper semiconductor layer 531, 631, 731 and the light-transmissive conductive layer 511, 611, 711. In one embodiment, the light-transmissive conductive layer 511, 611, 711 includes Indium Tin Oxide (ITO). The high resistance between ITO and the n-type semiconductor layer is harmful for conducting the current, and the current channel layer 512, 612, 712 can guide the current from the light-transmissive conductive layer 511, 611, 711 to the upper semiconductor layer 531, 631, 731 which includes the n-type semiconductor layer. If the upper semiconductor layer 531, 631, 731 includes gallium nitride (GaN) series n-type semiconductor layer, the current channel layer 512, 612, 712 includes titanium nitride (TiNₓ). If the upper semiconductor layer 531, 631, 731 includes aluminum gallium indium phosphide (AlGaInP) series n-type semiconductor layer, the current channel layer 512, 612, 712 includes germanium gold (GeAu). FIG. 5B shows a top view of the common conductive structure 4, the first chip 5, the second chip 6, and the third chip 7. In one embodiment, a shape of the current channel layer 512, 612, 712 is point-like and is substantially located at the center of the surface of the upper semiconductor layer 531, 631, 731. As shown in FIG. 5A, the current paths are illustrated by dashed lines in the first chip 5, the second chip 6, and the third chip 7. The current channel layer 512, 612, 712 is used to drive current from the center of the upper semiconductor layer 531, 631, 731, so the current flowing through the outer wall of the first semiconductor stack 53, the second semiconductor stack 63, and the third semiconductor stack 73 to generate excessive non-radiative recombination which leads to a reduction in the luminous efficiency of the first chip 5, the second chip 6, and the third chip 7 can be reduced.

As shown in FIG. 1, the common conductive structure 4, the first chip 5, the second chip 6, and the third chip 7 have the same or similar height H1. The dielectric layer 3 surrounds the common conductive structure 4, the first chip 5, the second chip 6, and the third chip 7, respectively. The dielectric layer 3 is coplanar with the top electrode 41 of the common conductive structure 4, the upper electrode 51 of the first chip 5, the upper electrode 61 of the second chip 6, and the upper electrode 71 of the third chip 7 to form a first common surface 31. The dielectric layer 3 is coplanar with the bottom electrode 42 of the common conductive structure 4, the lower electrode 52 of the first chip 5, the lower electrode 62 of the second chip 6 and the lower electrode 72 of the third chip 7 to form a second common surface 32. The light-transmissive carrier 1 covers the first common surface 31. The surface 11 of the light-transmissive carrier 1 is connected to the first common surface 31 through the light-transmissive conductive layer 2. The light-transmissive carrier 1 is used to support a structure made of the dielectric layer 3, the common conductive structure 4, the first chip 5, the second chip 6, and the third chip 7.

The material of the dielectric layer 3 includes epoxy, silicone, or photo-imageable dielectric (PID), wherein the photo-imageable dielectric can be formed into a thin film by a spin-coating process, and then the thin film can be processed into different shapes by using a patterning process of photomask and UV light irradiation. The photo-imageable dielectric can be cured at a low temperature and has an excellent metal adhesion and electrical insulation. In one embodiment, the dielectric layer 3 includes a dark material, such as carbon black, so that the transmittance of the dielectric layer 3 to the first light, the second light, and the third light is less than 50% to avoid the crosstalk between the first chip 5, the second chip 6, and the third chip 7 to block the common bonding pad 81, the first bonding pad 82, the second bonding pad 83, and the third bonding pad 84 for increasing the display contrast of display device 900A.

The material of the light-transmissive carrier 1 includes epoxy, silicone, glass, sapphire substrate, or ceramic substrate. The light-transmissive carrier 1 has a thickness between 10 μm and 1000 μm, and has a transmittance over 80% for visible light with peak wavelength or dominant wavelength between 440 nm and 660 nm. The material of the light-transmissive conductive layer 2 includes Indium Tin Oxide (ITO), and has a transmittance over 80% for visible light with a dominant wavelength or peak wavelength between 440 nm and 660 nm. The light-transmissive conductive layer 2 directly contacts the top electrode 41, the upper electrode 51, the upper electrode 61, and the upper electrode 71 to make the common conductive structure 4, the first chip 5, the second chip 6, and the third chip 7 being electrically connected to each other. The common bonding pad 81, the first bonding pad 82, the second bonding pad 83, and the third bonding pad 84 are respectively connected to the bottom electrode 42, the lower electrode 52, the lower electrode 62, and the lower electrode 72 for the current flowing to drive the first chip 5, the second chip 6, and the third chip 7 to emit lights. The materials of the common bonding pad 81, the first bonding pad 82, the second bonding pad 83, and the third bonding pad 84 include metal, such as copper, tin, aluminum, silver, palladium, gold, or laminates thereof.

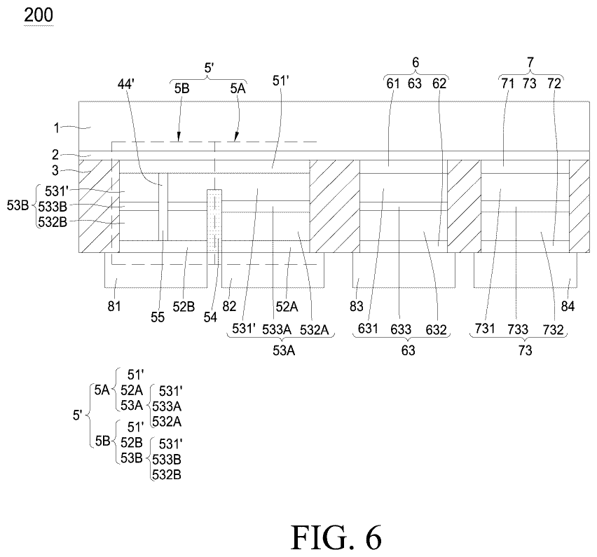

FIG. 6 shows a pixel structure 200 according to an embodiment. The pixel structure 200 can be used as the pixel 91 of the display device 900A as shown in FIG. 2. The pixel structure 200 has a first chip 5′. The first chip 5′ includes a light-emitting region 5A connected to the first bonding pad 82, a conductive region 5B connected to the common bonding pad 81, and an insulating layer 54 partially isolates the light-emitting region 5A and the conductive region 5B from each other, wherein the insulating layer 54 can be formed during the manufacturing process of the first chip 5′. In another embodiment, the insulating layer 54 is formed during the process of forming the dielectric layer 3. The light-emitting region 5A serves as the first chip 5 of the pixel structure 100 to emit the first light, and the conductive region 5B serves as the common conductive structure 4 of the pixel structure 100 to conduct current between the light-transmissive conductive layer 2 and the common bonding pad 81 without emitting light. In one embodiment, the light-emitting region 5A and the conductive region 5B share an upper electrode 51′. The light-emitting region 5A includes a lower electrode 52A and a light-emitting stack region 53A located between the upper electrode 51′ and the lower electrode 52A. The light-emitting stack region 53A has a first upper semiconductor layer 531′ connected to the upper electrode 51′, a first lower semiconductor layer 532A connected to the lower electrode 52A, and a first light-emitting layer 533A located between the first upper semiconductor layer 531′ and the first lower semiconductor layer 532A.

As shown in FIG. 6, the conductive region 5B includes a lower electrode 52B, a conductive stack region 53B located between the upper electrode 51′ and the lower electrode 52B, and a conductive portion 44′ located in and penetrating the conductive stack region 53B to connect the upper electrode 51′ and the lower electrode 52B. The conductive stack region 53B and the light-emitting stack region 53A share a first upper semiconductor layer 531′. The conductive stack region 53B also includes a first lower semiconductor layer 532B connected to the lower electrode 52B, and an MQW structure 533B located between the first upper semiconductor layer 531′ and the first lower semiconductor layer 532B. The insulating layer 54 separates the light-emitting stack region 53A and the conductive stack region 53B, and separates the lower electrode 52A and the lower electrode 52B. The current flows into the light-transmissive conductive layer 2 via the lower electrode 52B, the conductive portion 44′, and the upper electrode 51′ when the current flows from the common bonding pad 81 to the conductive stack region 53B. Then, the current flows into the light-emitting stack region 53A, the second chip 6, and the third chip 7 through the light-transmissive conductive layer 2 to emit the first light, the second light, and the third light. The intensities of the first light, the second light, and the third light are determined based on the current input from the first bonding pad 82 to the light-emitting stack region 53A, the current input from the second bonding pad 83 to the second chip 6, and the current input from the third bonding pad 84 to the third chip 7, through an external circuit (not shown).

As shown in FIG. 6, the material and structure of the upper electrode 51′ of the pixel structure 200 can be referred to the aforementioned paragraphs and drawings related to the upper electrode 51 of the pixel structure 100. The materials and structures of the light-emitting stack region 53A and the conductive stack region 53B can be referred to the aforementioned paragraphs and drawings related to the first semiconductor stack 53 of the pixel structure 100. In the pixel structure 200, the materials and structures of the first light-emitting layer 533A and the MQW structure 533B can be referred to the aforementioned paragraphs and drawings related to the first light-emitting layer 533 of the pixel structure 100. The materials and structures of the first lower semiconductor layer 532A and the first lower semiconductor layer 532B can be referred to the aforementioned paragraphs and drawings related to the first lower semiconductor layer 532 of the pixel structure 100. The materials and structures of the lower electrode 52A and the lower electrode 52B can be referred to the aforementioned paragraphs and drawings related to the lower electrode 52 of the pixel structure 100. In one embodiment, the conductive region 5B has a through hole 55 penetrating the conductive stack region 53B, and the conductive portion 44′ is disposed in the through hole 55 while the conductive portion 44′ completely or partially fill the through hole 55 and directly contacts the conductive stack region 53B. The material and structure of the conductive portion 44′ can be referred to the aforementioned paragraphs and drawings related to the conductive portion 44 of the pixel structure 100. In another embodiment, the conductive region 5B has an insulating layer (not shown) disposed in the through hole 55 to isolate the conductive portion 44′ from the semiconductor stack of the conductive stack region 53B.

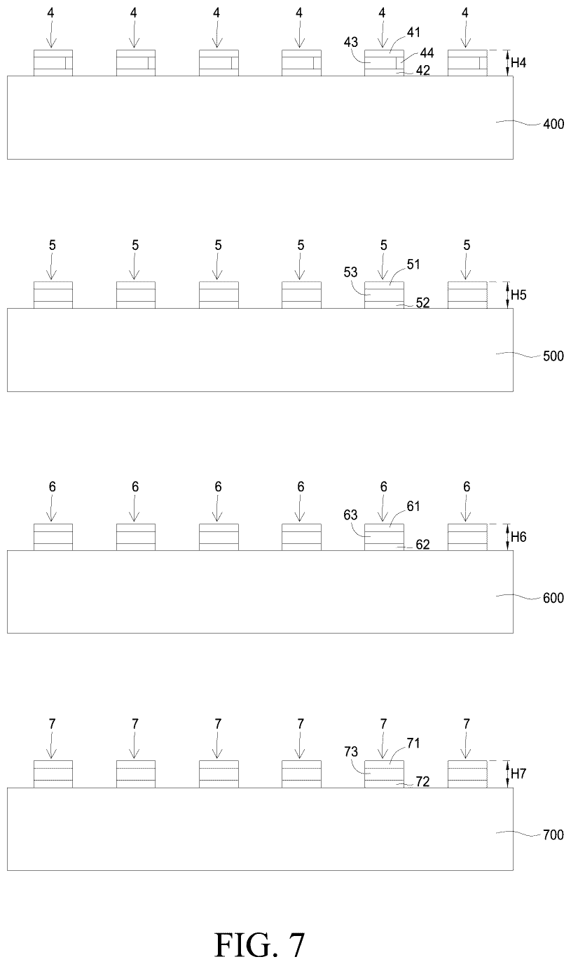

FIGS. 7 to 11 show a manufacturing process of the pixel structure 100 according to an embodiment. As shown in FIG. 7, a plurality of common conductive structures 4, a plurality of first chips 5, a plurality of second chips 6, and a plurality of third chips 7 are provided on the temporary carriers 400, 500, 600, 700, respectively. The common conductive structure 4 has a height H4, the first chip 5 has a height H5, the second chip 6 has a height H6, and the third chip 7 has a height H7. Each of the temporary carriers 400, 500, 600, 700 includes a substrate and an adhesive layer (not shown). The substrate is a sapphire substrate, a glass substrate, or a silicon substrate. The adhesive layer includes BCB (Benzocyclobutene), UV glue, thermal dissociation glue, epoxy or silicone, and can be used to temporarily fix the common conductive structures 4, the first chips 5, the second chips 6, the second chips 6, and the third chips 7.

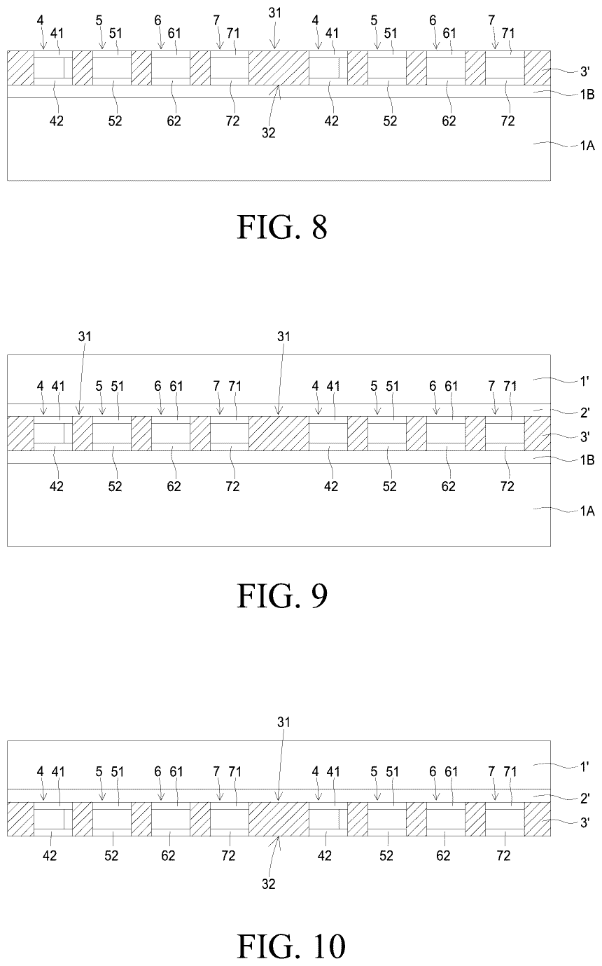

As shown in FIG. 8, portions of the common conductive structures 4, the first chips 5, the second chips 6, and the third chips 7 are sequentially transferred from the temporary carriers 400, 500, 600, 700 and temporarily fixed on another temporary carrier 1A. The common conductive structures 4, the first chips 5, the second chips 6, and the third chips 7 are arrange by referring to the positions of the common conductive structure 4, the first chip 5, the second chip 6, and the third chip 7 in the pixel structure 100 as shown in FIG. 1. Each of the common conductive structures 4, the first chips 5, the second chips 6 and the third chips 7 has a bottom electrode 42 or a lower electrode 52, 62, 72 facing the temporary carrier 1A and is temporarily fixed on the temporary carrier 1A by an adhesive layer 1B, wherein the adhesive layer 1B includes BCB, UV glue, thermal dissociation glue, epoxy, or silicone. Next, a dielectric material is covered on the temporary carrier 1A to form a dielectric layer 3′, wherein the material of the dielectric layer 3′ can be referred to the aforementioned paragraphs related to the dielectric layer 3. The method of forming the dielectric layer 3′ includes a high-temperature lamination process, a patterning process, or a molding process. The dielectric layer 3′ surrounds and exposes the top electrode 41 of the common conductive structures 4, and the upper electrodes 51, 61, 71 of the first chips 5, the second chips 6, and the third chips 7. The upper surface of the dielectric layer 3′ is coplanar with the upper surface of the top electrode 41 and the upper surfaces of the upper electrodes 51, 61, 71 to form a first common surface 31, and the lower surface of the dielectric layer 3′ is coplanar with the lower surface of the bottom electrode 42 and the lower surfaces of the lower electrodes 52, 62, 72 to form a second common surface 32 with a flat plane. In one embodiment, the height H4 of the common conductive structure 4, the height H5 of the first chip 5, the height H6 of the second chip 6, and the height H7 of the third chip 7 are the same, and the top electrode 41 and the upper electrodes 51, 61, 71 have a flat surface. Therefore, the first common surface 31 is a flat surface. In another embodiment, the height H4 of the common conductive structure 4, the height H5 of the first chip 5, the height H6 of the second chip 6, and the height H7 of the third chip 7 are partially or completely different, so the first common surface 31 is an uneven surface.

As shown in FIG. 9, a light-transmissive conductive layer 2′ is formed on the first common surface 31 to electrically connect the top electrode 41 and the upper electrodes 51, 61, 71 together. A light-transmissive carrier 1′ is provided on the light-transmissive conductive layer 2′ and is connected to the first common surface 31 through the light-transmissive conductive layer 2′. The structures and materials of the light-transmissive carrier 1′ and the light-transmissive conductive layer 2′ can be referred to the above-mentioned relevant paragraphs and drawings. In another embodiment, the first common surface 31 is an uneven surface, and the light-transmissive conductive layer 2′ is conformally formed on the first common surface 31 and also has an uneven surface. The light-transmissive carrier 1′ is adhered to the light-transmissive conductive layer 2′ through a light-transmissive adhesive layer (not shown), such as BCB, epoxy, or silicone, or the light-transmissive carrier 1′ can be formed on the uneven first common surface 31 with a thermosetting light-transmissive adhesive film, such as thermosetting epoxy, through a hot-pressing process.

As shown in FIG. 10, the adhesion of the adhesive layer 1B can be reduced by heating with a furnace tube, irradiating ultraviolet (UV) light, or irradiating a laser beam, such as a UV laser beam with a wavelength between 315 nm and 400 nm, or an infrared (IR) laser beam with a wavelength between 1000 nm and 1100 nm, or other methods to remove the temporary carrier 1A and expose the second common surface 32.

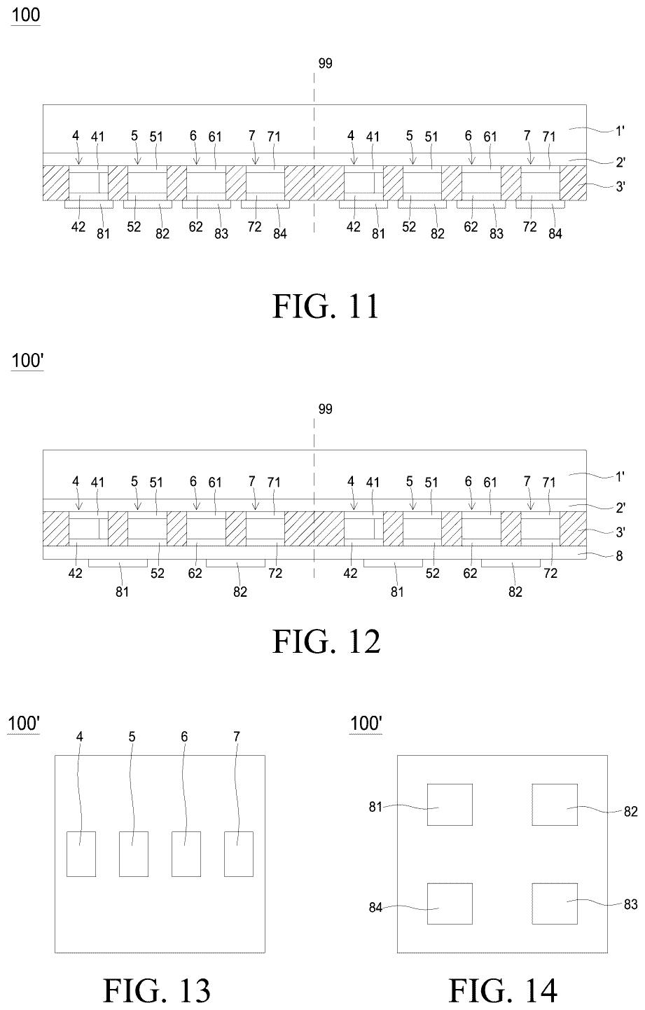

As shown in FIG. 11, the common bonding pad 81, the first bonding pad 82, the second bonding pad 83, and the third bonding pad 84 are formed on the second common surface 32 to connect the bottom electrode 42 and the lower electrode 52, 62, 72, respectively. Finally, a plurality of pixel structures 100 is formed by a cutting process along the dotted line 99.

FIG. 12 shows a cross-sectional view of a pixel structure 100′ according to an embodiment. After the steps shown in FIG. 10, a circuit redistribution layer 8 is formed on the second common surface 32, and the common bonding pad 81, the first bonding pad 82, the second bonding pad 83, and the third bonding pad 84 are formed on the circuit redistribution layer 8 to connect the bottom electrode 42 and the lower electrode 52, 62, 72, respectively. Finally, a plurality of pixel structures 100′ is formed by a cutting process along the dotted line 99.

FIG. 13 shows a top view of the pixel structure 100′ according to an embodiment, and FIG. 14 shows a bottom view of the pixel structure 100′ according to an embodiment. As shown in FIG. 13, the common conductive structure 4, the first chip 5, the second chip 6, and the third chip 7 of the pixel structure 100′ are arranged in a line. As shown in FIG. 14, the common bonding pad 81, the first bonding pad 82, the second bonding pad 83, and the third bonding pad 84 of the pixel structure 100′ are arranged in an array. Since the common conductive structure 4, the first chip 5, the second chip 6, and the third chip 7 are arranged in a line, the bottom electrode 42 and the lower electrodes 52, 62, 72 are also arranged in a line. In other words, the arrangement of the common bonding pad 81, the first bonding pad 82, the second bonding pad 83, and the third bonding pad 84 is different from the arrangement of the bottom electrode 42 and the lower electrodes 52, 62, 72.

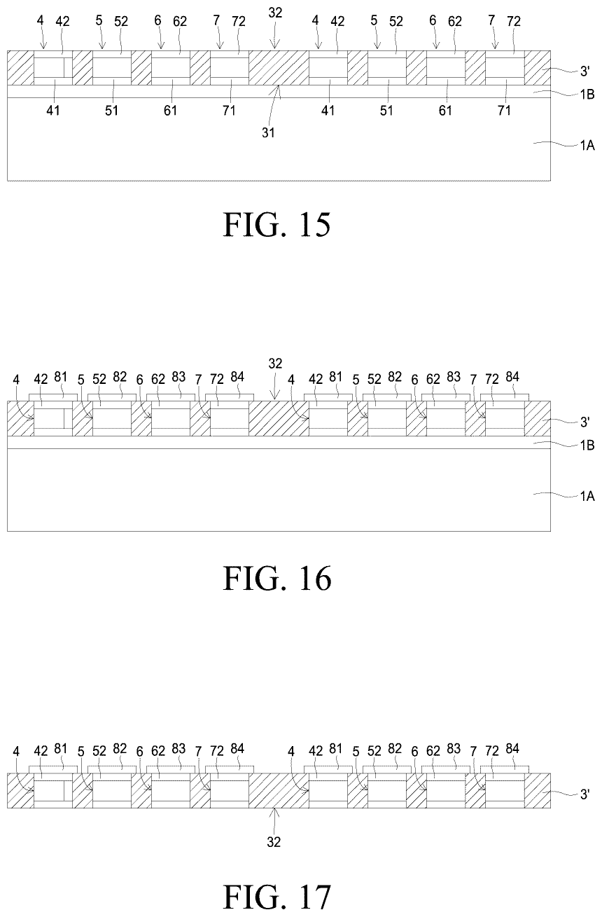

FIGS. 15 to 18 show a manufacturing process of a pixel structure 100 according to an embodiment. As shown in FIG. 15, parts of the common conductive structures 4, the first chips 5, the second chips 6, and the third chips 7 are sequentially transferred and temporarily fixed from the temporary carriers 400, 500, 600, 700 shown in FIG. 7 to the temporary carrier 1A, and arranged according to the positions of the common conductive structure 4, the first chip 5, the second chip 6, and the third chip 7 of the pixel structure 100 shown in FIG. 1. Each of the common conductive structures 4, the first chips 5, the second chips 6 and the third chips 7 has the top electrode 41 or the upper electrode 51, 61, 71 facing the temporary carrier 1A and is temporarily fixed on the temporary carrier 1A by an adhesive layer 1B, wherein the adhesive layer includes BCB, UV glue, thermal dissociation glue, epoxy, or silicone. Next, a dielectric material is arranged on the temporary carrier 1A to form a dielectric layer 3′. The dielectric layer 3′ surrounds and exposes the bottom electrode 42 and the lower electrodes 52, 62, 72 of the common conductive structure 4, the first chip 5, the second chip 6, and the third chip 7. The upper surface of the dielectric layer 3′ is coplanar with the upper surface of the bottom electrode 42 and the upper surfaces of the lower electrodes 52, 62, 72 to form a second common surface 32, and the lower surface of the dielectric layer 3′ is coplanar with the lower surface of the top electrode 41 and the lower surfaces of the upper electrodes 51, 61, 71 to form a first common surface 31 with a flat plane. In one embodiment, the heights H4, H5, H6, H7 of the common conductive structure 4, the first chip 5, the second chip 6, and the third chip 7 are the same, and the bottom electrode 42 and the lower electrodes 52, 62, 72 have a flat surface. Therefore, the second common surface 32 is a flat surface. In another embodiment, the heights H4, H5, H6, H7 of the common conductive structure 4, the first chip 5, the second chip 6, and the third chip 7 are partially or completely different, so the second common surface 32 is an uneven surface.

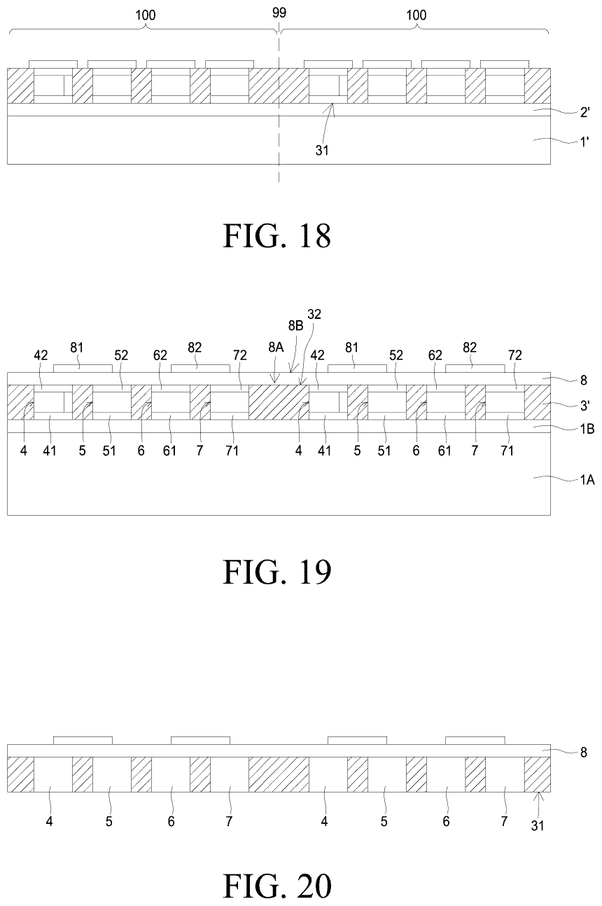

FIG. 16 shows a manufacturing step of the bonding pads 81-84. If the second common surface 32 is a flat surface, the common bonding pad 81, the first bonding pad 82, the second bonding pad 83, and the third bonding pad 84 are formed on the second common surface 32 to connect the bottom electrode 42 and the lower electrode 52, 62, 72, respectively. As shown in FIG. 17, the temporary carrier 1A is removed to expose the first common surface 31 which has a flat plane. Next, as shown in FIG. 18, a light-transmissive conductive layer 2′ is formed on the first common surface 31 to electrically connect the top electrode 41 and the upper electrodes 51, 61, 71 together. A light-transmissive carrier 1′ is set below the light-transmissive conductive layer 2′, and is connected to the first common surface 31 through the light-transmissive conductive layer 2′. Finally, a cutting process is performed along the dotted line 99 to form a plurality of pixel structures 100 that is separated from each other.

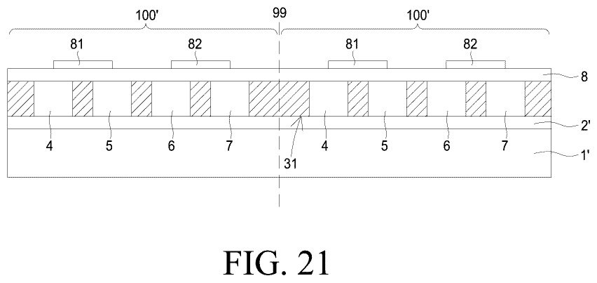

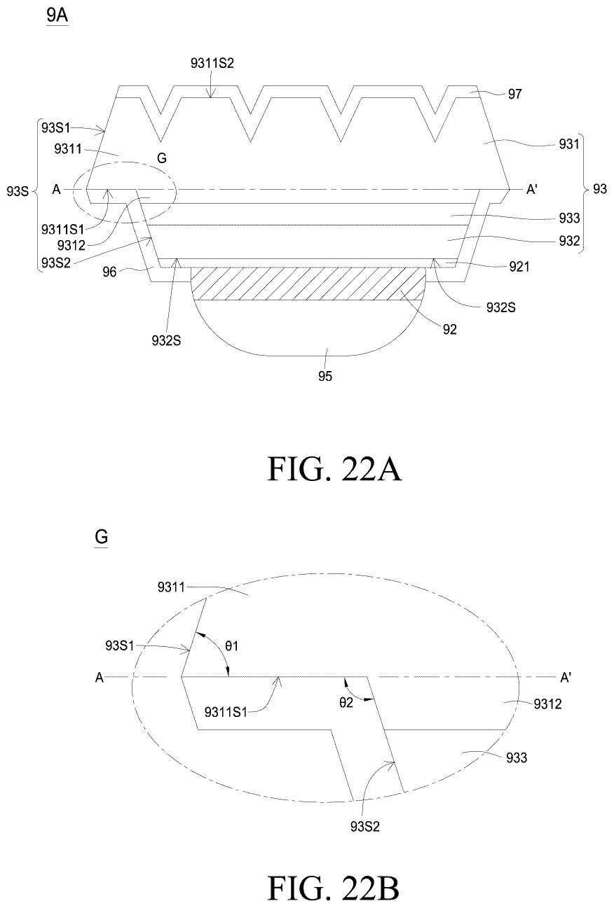

FIGS. 19 to 21 show a manufacturing process of a pixel structure 100′ according to an embodiment. After the structure shown in FIG. 15, if the second common surface 32 is an uneven surface as shown in FIG. 19, a circuit redistribution layer 8 is formed on the second common surface 32, and then the common bonding pad 81, the first bonding pad 82, the second bonding pad 83, and the third bonding pad 84 are formed on the circuit redistribution layer 8 to connect the bottom electrode 42 and the lower electrode 52, 62, 72, respectively. The arrangement of the common bonding pad 81, the first bonding pad 82, the second bonding pad 83, and the third bonding pad 84 can be the same as or different from the arrangement of the bottom electrode 42 and the lower electrodes 52, 62, 72. As shown in FIG. 19, a lower surface 8A of the circuit redistribution layer 8 can be conformally formed on the uneven second common surface 32, and an upper surface 8B opposite the lower surface 8A can be a flat or uneven surface. A common bonding pad 81, a first bonding pad 82, a second bonding pad 83, and a third bonding pad 84 (not shown) are formed on the upper surface 8B of the circuit redistribution layer 8. Then, as shown in FIG. 20, the temporary carrier 1A is removed to expose the first common surface 31. Next, as shown in FIG. 21, a light-transmissive conductive layer 2′ is formed on the first common surface 31 to electrically connect the top electrode 41 and the upper electrodes 51, 61, 71 together. A light-transmissive carrier 1′ is provided below the light-transmissive conductive layer 2′ and is connected to the first common surface 31 through the light-transmissive conductive layer 2′. Finally, a plurality of pixel structures 100′ is formed by a cutting process along the dotted line 99. FIG. 22A shows a cross-sectional view of a chip 9A according to an embodiment, wherein the detailed description of the chip 9A can be referred to the first chip 5, the second chip 6, and the third chip 7 in FIG. 4 and FIG. 5A and corresponding description. The chip 9A includes a semiconductor stack 93, an upper electrode 97 located above the semiconductor stack 93, and a lower electrode 92 located below the semiconductor stack 93. FIG. 22B shows an enlarged view of area G in FIG. 22A.

The semiconductor stack 93 includes an upper semiconductor layer 931, a lower semiconductor layer 932, and an MQW structure 933 located between the upper semiconductor layer 931 and the lower semiconductor layer 932 for emitting a light. The material of the upper semiconductor layer 931 can be referred to the relevant descriptions of the first upper semiconductor layer 531, the second upper semiconductor layer 631, and the third upper semiconductor layer 731, and the material of the lower semiconductor layer 932 can be referred to the relevant descriptions of the first lower semiconductor layer 532, the second lower semiconductor layer 632, and the third lower semiconductor layer 732. The chip 9A has an upper surface 9311S2, a lower surface 932S opposite to the upper surface 9311S2, and a plurality of side surfaces 93S. Each side surface 93S is located between the upper surface 9311S2 and the lower surface 932S. The light formed by the MQW structure 933 can be emitted outward from the upper surface 9311S2, wherein the upper surface 9311S2 is a rough surface to increase the light extraction efficiency of the chip 9A. In one embodiment, the upper surface 9311S2 is a regular/irregular rough surface, wherein the average roughness (Ra) of the upper surface 9311S2 is between 0.1 μm and 1 μm. The lower surface 932S is a flat surface, and the average roughness of the lower surface 932S is smaller than that of the upper surface 9311S2. The side surface 93S has an upper side surface 93S1 connected to the upper surface 9311S2, a lower side surface 93S2 connected to the lower surface 932S, and a middle side surface 9311S1 located between and connected to the upper side surface 93S1 and the lower side surface 93S2. As shown in FIG. 22B, an included angle θ1 is between the upper side surface 93S1 and the middle side surface 9311S1, and an included angle θ2 is between the lower side surface 93S2 and the middle side surface 9311S1. In one embodiment, the included angle θ1 is an acute angle, and the included angle θ2 is an obtuse angle. The included angle θ1 is between 35 degrees and 85 degrees, and the included angle θ2 is between 95 degrees and 145 degrees. In the cross-sectional view of the chip 9A as shown in FIG. 22A, the dotted line AA′ passes through and is parallel to the middle side surface 9311S1. In one embodiment, the dotted line AA′ divides the upper semiconductor layer 931 into a first upper semiconductor layer 9311 and a second upper semiconductor layer 9312. The first upper semiconductor layer 9311 has the upper surface 9311S2, the upper side surface 93S1, and the middle side surface 9311S1. The second upper semiconductor layer 9312 is located between the first upper semiconductor layer 9311 and the MQW structure 933, and is connected to the MQW structure 933. The maximum width of the first upper semiconductor layer 9311 is greater than the maximum width of the second upper semiconductor layer 9312, and the middle side surface 9311S1 of the first upper semiconductor layer 9311 is in contact with the second upper semiconductor layer 9312.

As shown in FIG. 22A, in one embodiment, the material and structure of the upper electrode 97 can be referred to the aforementioned relevant descriptions of the upper electrodes 51, 61, 71, and the material and structure of the lower electrode 92 can be referred to the aforementioned relevant descriptions of the lower electrodes 52, 62, 72. The upper electrode 97 conformally covers the upper surface 9311S2, and the lower electrode 92 covers a part of the lower surface 932S. In one embodiment, the chip 9A further includes an ohmic contact layer 921 located between the lower semiconductor layer 932 and the lower electrode 92 to reduce the contact resistance between the lower semiconductor layer 932 and the lower electrode 92. The ohmic contact layer 921 includes a semiconductor material such as gallium arsenide (GaAs), or an oxide conductive material such as Indium Tin Oxide (ITO).

As shown in FIG. 22A, in one embodiment, the chip 9A further optionally includes an insulating protective layer 96 to cover the middle side surface 9311S1, the lower side surface 93S2, and a part of the lower surface 932S uncovered by the lower electrode 92. The insulating protective layer 96 includes a dielectric material, such as silicon oxide (SiOₓ) or silicon nitride (SiNₓ). The thickness of the insulating protective layer 96 is between 1 nm and 100 nm and is smaller than the thickness of the lower electrode 92.

As shown in FIG. 22A, in one embodiment, the chip 9A optionally further includes an electrical connection portion 95 to cover the lower electrode 92 and connect to an external circuit (not shown). In one embodiment, the electrical connection portion 95 has an arc-shaped surface, and the maximum thickness of the electrical connection portion 95 is greater than the thickness of the lower electrode 92. The material of the electrical connection portion 95 includes metal, such as tin, silver, or gold.

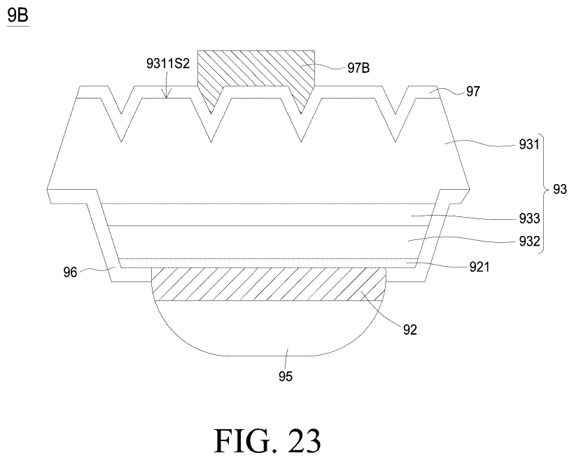

FIG. 23 shows a cross-sectional view of a chip 9B according to an embodiment. The chip 9B includes a metal electrode 97B formed on a portion of the upper electrode 97. The metal electrode 97B can conduct the current into the upper electrode 97. When the chip 9B is used as the first chip 5, the second chip 6, or the third chip 7 in the pixel structure 100, the metal electrode 97B directly contacts the light-transmissive conductive layer 2 of the pixel structure 100 to reduce the resistance between the upper electrode 97 of the chip 9B and the light-transmissive conductive layer 2 of the pixel structure 100. The metal electrode 97B includes titanium, germanium, or gold. In one embodiment, in a top view, the metal electrode 97B has a circular or square contour, and is substantially located at the center of the upper surface 9311S2 of the upper semiconductor layer 931.

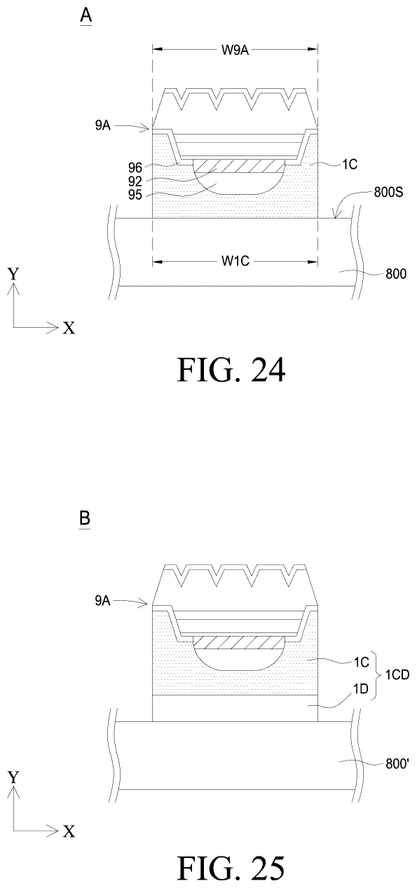

FIG. 24 shows a cross-sectional view of an arrangement structure A in which the chip 9A is temporarily fixed on a temporary carrier 800. The detailed description of the chip 9A can be referred to the first chip 5, the second chip 6, and the third chip 7 shown in FIG. 7 and corresponding description. In one embodiment, in an X-axis direction, a width WIC of an adhesive layer 1C is equal to or smaller than a maximum width W9A of the chip 9A. The temporary carrier 800 includes a sapphire substrate, a glass substrate, or a silicon substrate. The adhesive layer 1C includes BCB or epoxy. In subsequent process, a laser beam can be used to irradiate the adhesive layer 1C to reduce the adhesion of the adhesive layer 1C or to remove the adhesive layer 1C to separate the chip 9A from the temporary carrier 800. The laser beam includes a UV laser beam with a wavelength between 200 nm and 400 nm, or an IR laser beam with a wavelength between 1000 nm and 1100 nm.

FIG. 25 shows a cross-sectional view of an arrangement structure B in which the chip 9A is temporarily fixed on a temporary carrier 800′ via a dual adhesion layer structure 1CD according to another embodiment. The arrangement structure B includes an adhesive layer 1D located between the adhesive layer 1C and the temporary carrier 800′, wherein the adhesive layer 1C and the adhesive layer 1D are collectively referred to as a dual adhesion layer structure 1CD. The adhesive layer 1C and the adhesive layer 1D include different adhesive materials. The laser beam energy required to reduce the adhesion of the adhesive layer 1D or to remove the adhesive layer 1D is less than the laser beam energy required to reduce the adhesion of the adhesive layer 1C or to remove the adhesive layer 1C. In one embodiment, the laser beam energy required to reduce the adhesion of the adhesive layer 1D or remove the adhesive layer 1D is 50 mJ/cm² to 200 mJ/cm², and the laser beam energy required to reduce the adhesion of the adhesive layer 1C or remove the adhesive layer 1C is 200 mJ/cm² to 1000 mJ/cm². Therefore, compared with the arrangement A shown in FIG. 24, the chip 9A is more easily separated from the temporary carrier 800′ by irradiating the adhesive layer 1D with the laser beam. In one embodiment, the adhesive layer 1C includes epoxy, and the adhesive layer 1D includes polyimide (PI). Polyimide has higher laser absorption rate than epoxy at a wavelength of 200 nm to 250 nm. To decompose polyimide, carbon-nitrogen (C—N) bond needs be broken by laser. To decompose epoxy, carbon-carbon (C—C) bond and carbon-oxygen (C—O) bond need be broken by laser. The bond energy of C—N bond in polyimide is 3.17 eV. The bond energy of C—C bond and C—O bond in epoxy resin are 3.60 eV and 3.71 eV, respectively. Compared with epoxy, polyimide has a higher absorption rate for lasers with wavelengths between 200 nm and 250 nm and is easier to decompose. Therefore, the adhesive layer 1D is easier to reduce the adhesion or be removed by laser with a wavelength between 200 nm and 250 nm than the adhesive layer 1C. In one embodiment, the thickness of the adhesive layer 1C is greater than the thickness of the adhesive layer 1D. The thickness of the adhesive layer 1C is 2 μm to 20 μm, and the thickness of the adhesive layer 1D is 0.1 μm to 2 μm.

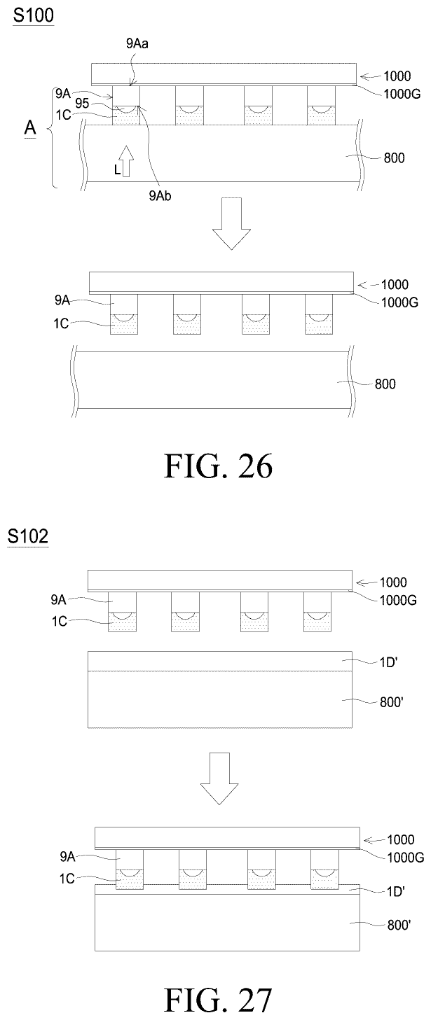

FIGS. 26 to 29 show a manufacturing process of the arrangement structure B according to an embodiment. FIG. 26 shows a schematic diagram of a step S100 for transferring a plurality of chips 9A from the temporary carrier 800 to a support substrate 1000 according to an embodiment. As shown in FIG. 26, in step S100, the plurality of chips 9A is provided on the temporary carrier 800 through the adhesive layer 1C, and the plurality of chips 9A is separated from each other and fixed on the temporary carrier 800. The detailed description of arrangement structure B can be referred to the arrangement structure A shown in FIG. 24 and related paragraphs. The chip 9A includes a front side 9Aa and back side 9Ab. The front side 9Aa faces away from the temporary carrier 800, and the back side 9Ab faces toward the temporary carrier 800. The chip 9A includes an electrical connection portion 95 on the back side 9Ab facing the temporary carrier 800. The adhesive layer 1C is located between the back side 9Ab of the chip 9A and the temporary carrier 800 to fix the chip 9A on the temporary carrier 800. The support substrate 1000 includes an adhesive layer 1000G facing and adhering the front side 9Aa of the plurality of chips 9A. The support substrate 1000 includes a thermal release tape, an UV release tape, a chemical release tape, a heat-resistant tape, a blue tape, or a tape with a dynamic release layer (DRL). According to another embodiment, the chip 9A can be replaced by the chip 9B shown in FIG. 23, and the adhesive layer 1000G of the support substrate 1000 adheres to the metal electrode 97B of the chip 9B. Next, a laser lift-off process is used. Irradiating laser at the interface between the temporary carrier 800 and the adhesive layer 1C to reduce the adhesion of the adhesive layer 1C or remove part of the adhesive layer 1C to remove the temporary carrier 800 and expose the adhesive layer 1C.

Then, in step S102 as shown in FIG. 27, a temporary carrier 800′ and an adhesive layer 1D′ are provided, wherein the adhesive layer 1D′ is continuously distributed and disposed on the temporary carrier 800′ and has a uniform thickness between 0.05 μm and 5 μm. In one embodiment, the adhesive layer 1D′ includes a polymer. The glass transition temperature Tg of the polymer is, for example, between 100° C. and 110° C. The polymer is in a semi-cured state. In one embodiment, the polymer includes polyimide (PI). According to an embodiment, the method of making the adhesive layer 1D′ includes coating a liquid state material on the temporary carrier 800′ by spin coating, and then baking it at a temperature TO between 160° C. and 200° C., to make the liquid state material form the adhesive layer 1D′ that has no fluidity and has a cross-linked structure. At this time, the adhesive layer 1D′ has no adhesive property or only has slightly adhesive property. For example, if a flat metal with an area of 3*3 mm² is in contact with the adhesive layer 1D′, the pulling force required to separate the flat metal from the adhesive layer 1D′ is less than 1 gram. According to an embodiment, the adhesive layer 1D′ is formed on the temporary carrier 800′ through dip coating, screen printing, doctor blade coating, or other processes. Then, the adhesive layer 1D′ is heated at a first temperature T1, for example, 110-130° C., and the support substrate 1000 is moved so that the adhesive layer 1C on the chip 9A contacts the adhesive layer 1D′ on the temporary carrier 800′. If the adhesive layer 1D′ has a glass transition temperature Tg, the relationship between the first temperature T1 and the glass transition temperature Tg of the adhesive layer 1D′ satisfies formula (1):

0<(T1−Tg)/Tg≤70% (1)

Wherein T1 is the first temperature, and Tg is the glass transition temperature.

By applying the first temperature T1 in the above formula (1) to the adhesive layer 1D′, the adhesive layer 1D′ which is cross-linked and cured can be softened to generate a greater adhesion to the adhesive layer 1C on the chip 9A. For example, after the adhesive layer 1D′ is heated at the first temperature T1, a flat metal with an area of 3*3 mm² is brought into contact with the adhesive layer 1D′. After the adhesive layer 1D′ is cooled to room temperature (25° C.), the pulling force required to separate the flat metal and the adhesive layer 1D′ is greater than 500 grams. That is to say, the adhesive layer 1D′ has no adhesive property or only has slightly adhesive property before the adhesive layer 1D′ is heated to the first temperature T1, but the adhesive property of the adhesive layer 1D′ can be improved after the adhesive layer 1D′ is heated to the first temperature T1. At this time, the chip 9A can be properly fixed to the adhesive layer 1D′ without falling off easily when the adhesive layer 1C on the chip 9A contacts the adhesive layer 1D′. At this time, a part of the adhesive layer 1C on the chip 9A is buried in the adhesive layer 1D′. After the chip 9A is adhered to the adhesive layer 1D′, the heat applied to the adhesive layer 1D′ to maintain the first temperature T1 can be stopped, allowing the temperature of the adhesive layer 1D′ to fall back to a predetermined temperature, such as room temperature. After returning to room temperature, there is still an adhesion between the adhesive layer 1C on the chip 9A and the adhesive layer 1D′, so the chip 9A is still adhered on the adhesive layer 1D′.

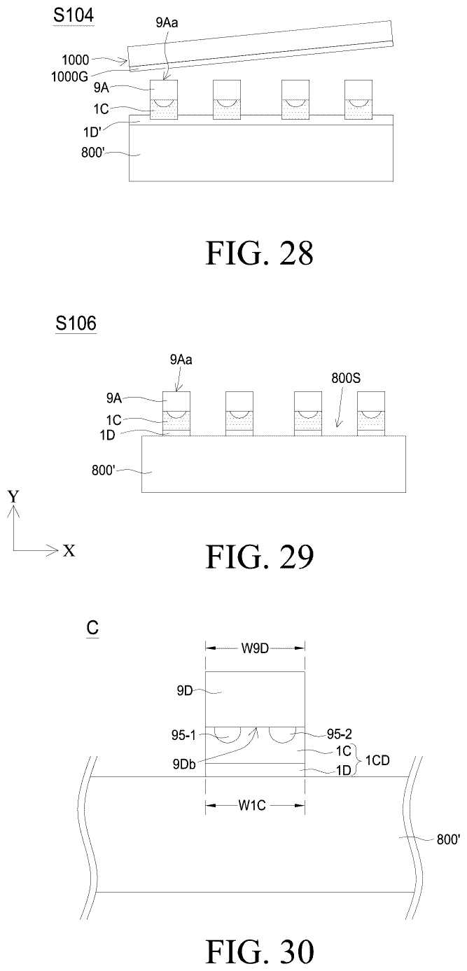

Then, in step S104 as shown in FIG. 28, the support substrate 1000 is peeled off through heating, UV light irradiation, laser lift-off, or peeling by external force to expose the front side 9Aa of the chip 9A.

Then, in step S106 as shown in FIG. 29, an etching process, such as an inductively coupled plasma (ICP) etching process, is performed along the −Y direction from the front side 9Aa of the chip 9A to etch the adhesive layer 1D′ that is uncovered by the chip 9A to expose the surface 800S of the temporary carrier 800′. A plurality of adhesive layer 1D exhibiting discrete distribution (discontinuity) is formed.

By performing steps S100 to S106 shown in FIGS. 26 to 29, a plurality of chips 9A is transferred from the temporary carrier 800 to the temporary carrier 800′. A plurality of chips 9A is located on the temporary carrier 800′ and separated from each other, and are fixed on the temporary carrier 800′ in the arrangement structure B shown in FIG. 25. According to an embodiment, the arrangement of the chips 9A on the temporary carrier 800′ can be similar or the same as the arrangement of the chips 9A on the temporary carrier 800.

FIG. 30 shows a cross-sectional view of an arrangement structure C in which a flip chip 9D is fixed on the temporary carrier 800′ according to an embodiment. The method of fixing the flip chip 9D to the temporary carrier 800′ can be referred to the dual adhesion layer structure 1CD shown in FIG. 25, wherein the flip chip 9D has a first electrical connection portion 95-1 and a second electrical connection portion 95-2 located on the back side 9Db and facing the temporary carrier 800′, and the adhesive layer 1C is provided on the back side 9Db of the flip chip 9D and covers the first electrical connection portion 95-1 and the second electrical connection portion 95-2. The structures and materials of the first electrical connection portion 95-1 and the second electrical connection portion 95-2 can be referred to the electrical connection portion 95 of the chip 9A in FIG. 22 and related paragraphs. The detailed description of the adhesive layers 1C and 1D can be referred to the adhesive layers 1C and 1D in FIG. 25 and related paragraphs. The maximum width W9D of the flip chip 9D is greater than or equal to the maximum width WIC of the adhesive layers 1C and 1D.

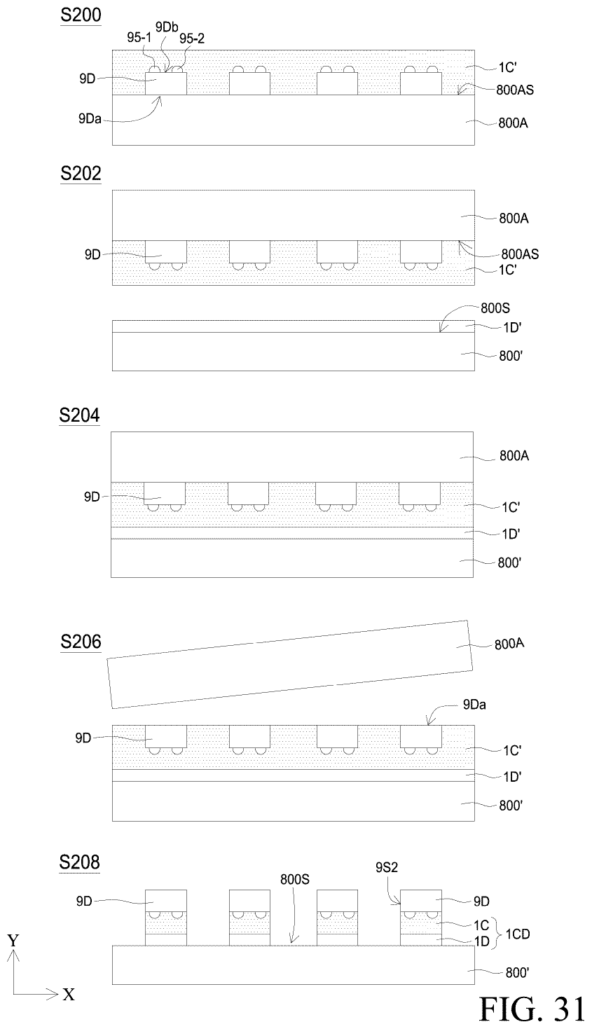

FIG. 31 shows steps S200 to S208 of forming the arrangement structure C according to an embodiment. In step S200, a plurality of flip chips 9D is temporarily fixed on the surface 800AS of the temporary carrier 800A. The adhesive layer 1C′ is formed on the surface 800AS of the temporary carrier 800A by coating or spin coating, and covers the plurality of flip chips 9D. The detailed description of the adhesive layer 1C′ can be referred to FIG. 24 and related paragraphs. The first electrical connection portion 95-1 and the second electrical connection portion 95-2 are located on the back side 9Db. The flip chip 9D contacts the temporary carrier 800A through the front side 9Da and is fixed on the temporary carrier 800A. According to one embodiment, the temporary carrier 800A is a growth substrate that can be used for epitaxial growth, and the flip chip 9D is formed on the growth substrate. The material of the growth substrate includes but are not limited to silicon (Si), germanium (Ge), lithium aluminate (LiAlO₂), zinc oxide (ZnO), silicon carbide (SiC), sapphire, gallium nitride (GaN), aluminum nitride (AlN), gallium arsenide (GaAs), and indium phosphide (InP). According to another embodiment, the temporary carrier 800A includes a non-epitaxial material or a non-growth substrate. When the temporary carrier 800A includes a non-epitaxial material or a non-growth substrate, a connection layer (not shown) is present between the front side 9Da of the flip chip 9D and the surface 800AS of the temporary carrier 800A. The material of the connecting layer is, for example, polymer, and the connection layer is used to temporarily fix the flip chip 9D to the temporary carrier 800A.

Next, step S202 is performed to provide a temporary carrier 800′ and an adhesive layer 1D′ continuously distributed on the surface 800S of the temporary carrier 800′. The manufacturing processes and structures of the temporary carrier 800′ and the adhesive layer 1D′ can be referred to the temporary carrier 800′ and the adhesive layer 1D′ in FIG. 27 and related paragraphs. The surface 800AS of the temporary carrier 800A faces the surface 800S of the temporary carrier 800′, so that the adhesive layer 1D′ faces the adhesive layer 1C′.

Next, as shown in step S204, the adhesive layer 1C′ is brought into contact with the adhesive layer 1D′. The temporary carrier 800′ and the temporary carrier 800A are adhered to each other through the adhesive layer 1C′ and the adhesive layer 1D′. The detailed description of the adhering process can be referred to the adhering process of the adhesive layer 1C and the adhesive layer 1D′ in FIG. 27 and related paragraphs.

Next, as shown in step S206, when the temporary carrier 800A is a growth substrate, the temporary carrier 800A can be separated from the flip chip 9D and the adhesive layer 1C′ using a laser lift-off process. When the temporary carrier 800A is a non-growth substrate, such as a heat-resistant tape, a blue tape or other adhesive films, the temporary carrier 800A can be peeled off by heating, ultraviolet irradiation, laser peeling, or peeling by external force to expose the front side 9Da of the flip chip 9D and the adhesive layer 1C′.

Next, as shown in step S208, an etching process, such as an inductively coupled plasma (ICP) etching process, is performed along the −Y direction from the front side 9Da of the flip chip 9D to etch the adhesive layer 1C′ and the adhesive layer 1D′ that are not covered by the flip chip 9D to expose the surface 800S of the temporary carrier 800′. A plurality of dual adhesion layer structure 1CD exhibiting discrete distribution (discontinuity) is formed.

By performing steps S200 to S208 shown in FIG. 31, a plurality of flip chips 9D is transferred from the temporary carrier 800A to the temporary carrier 800′. The plurality of flip chips 9D is located on the temporary carrier 800′ and separated from each other. Each flip chip 9D is fixed on the temporary carrier 800′ through the dual adhesion layer structure 1CD. According to an embodiment, the arrangement of the flip chips 9D on the temporary carrier 800′ can be similar to or the same as the arrangement of the flip chips 9D on the temporary carrier 800A.

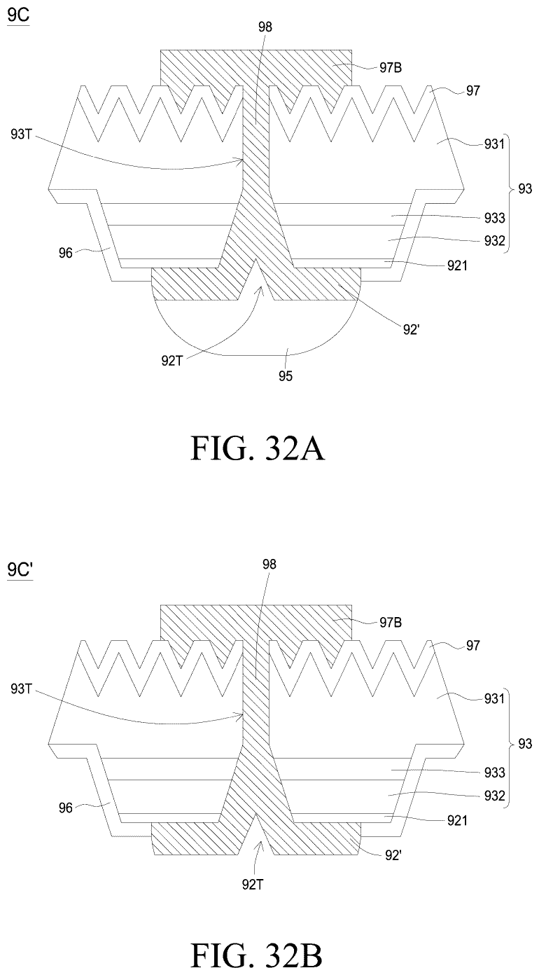

FIG. 32A shows a cross-sectional view of a chip 9C according to an embodiment. A difference between the chip 9C and the chip 9B shown in FIG. 23 is that the semiconductor stack 93 of the chip 9C has a through hole 93T penetrating the semiconductor stack 93. A conductive portion 98 fills in the through hole 93T and penetrates the semiconductor stack 93 to connect the metal electrode 97B and the bottom electrode 92′. The bottom electrode 92′ has a recessed portion 92T covering a lower opening of the through hole 93T and connected to the conductive portion 98. In one embodiment, the conductive portion 98, the metal electrode 97B, and the bottom electrode 92′ include the same material. The structure of the chip 9C can be referred to the common conductive structure 4 shown in FIG. 4. When the current flows into the chip 9C, the current flows through the conductive portion 98 rather than through the MQW structure 933 because the conductive portion 98 has a lower resistance than the MQW structure 933. Therefore, the chip 9C does not emit light. FIG. 32B shows a cross-sectional view of a chip 9C′ without the electrical connection portion 95 according to one embodiment. The structure of the chip 9C′ can be referred to FIG. 32A and related paragraphs.

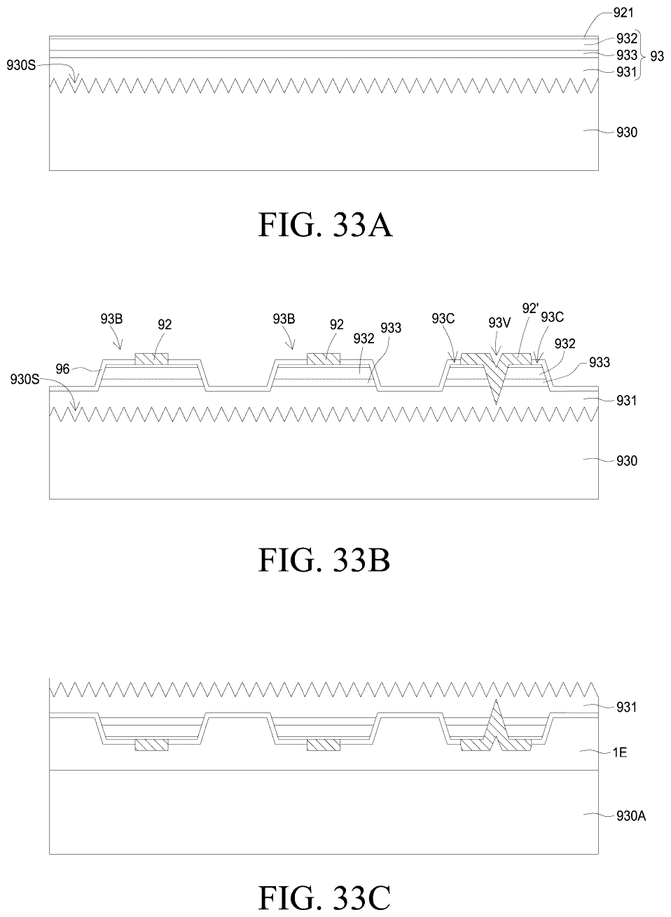

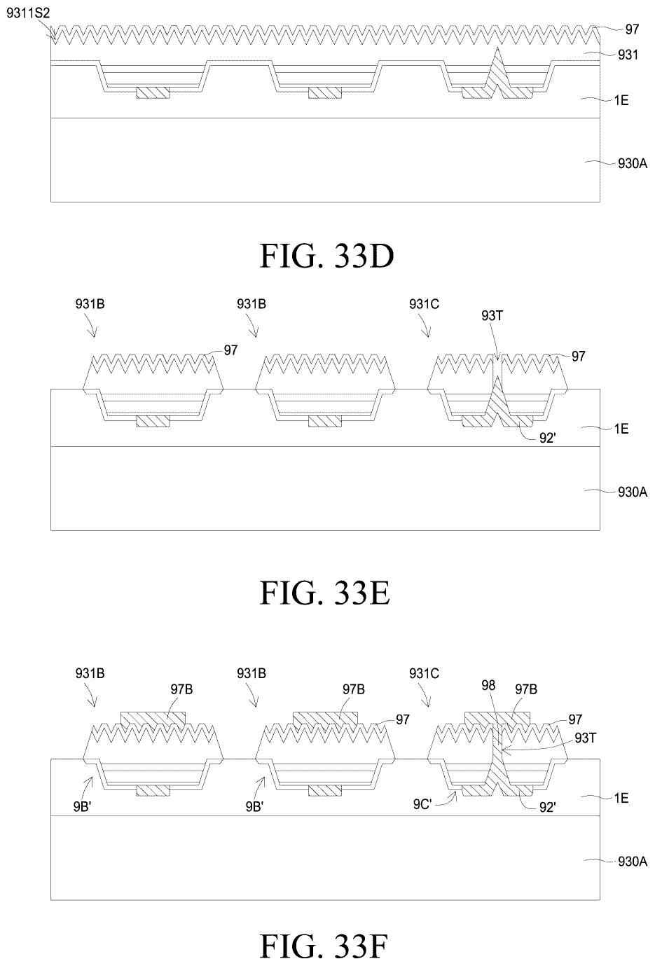

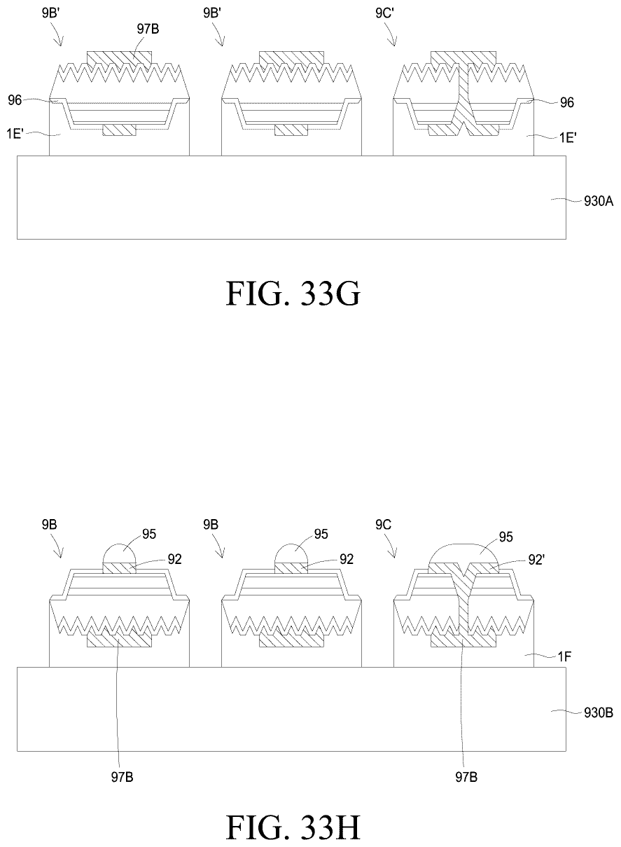

FIGS. 33A to 33H show a manufacturing process of the chips 9B and 9C according to an embodiment. As shown in FIG. 33A, a growth substrate 930 with a patterned surface 930S is provided. A semiconductor stack 93 is formed on the patterned surface 930S by epitaxial growth, and then an ohmic contact layer 921 is formed on the semiconductor stack 93. The semiconductor stack 93 includes an upper semiconductor layer 931, a lower semiconductor layer, and an MQW structure 933. The structures and materials of the growth substrate 930, the semiconductor stack 93, and the ohmic contact layer 921 can be referred to the above relevant descriptions.

As shown in FIG. 33B, the semiconductor stack 93 and the ohmic contact layer 921 are patterned through an etching process to form a plurality of platforms 93B, 93C and expose the upper semiconductor layer 931, wherein each of the platforms 93B, 93C has the lower semiconductor layer 932 and the MQW structure 933. As shown in FIG. 33B, two platforms 93C adjacent to each other in the cross-sectional view jointly form a V-shaped groove 93V. Then, the lower electrode 92 and the bottom electrode 92′ are formed on the platforms 93B and 93C, respectively. The bottom electrode 92′ covers two adjacent platforms 93C and fills the V-shaped groove 93V. The materials and structures of the lower electrode 92 and the bottom electrode 92′ can be referred to the lower electrodes 52, 62, 72 in the relevant paragraphs. Next, an insulating protective layer 96 is formed to conformally cover the upper semiconductor layer 931 and the platforms 93B, 93C and expose the lower electrode 92 and the bottom electrode 92′.

As shown in FIG. 33C, an adhesive layer 1E is provided on the platforms 93B and 93C by coating or spin coating, and then a temporary carrier 930A is provided on the adhesive layer 1E. The adhesive layer 1E fixes the temporary carrier 930A on the platforms 93B and 93C. The material of the adhesive layer 1E includes BCB (benzocyclobutene) or epoxy. In another embodiment, the adhesive layer 1E is made of the same material as the adhesive layers 1C and 1D. In the subsequent process, a laser beam can be used to irradiate the adhesive layer 1E to reduce the adhesion of the adhesive layer 1E or remove the adhesive layer 1E to separate the platforms 93B and 93C from temporary carrier 930A. Next, a laser lift-off process is used. Irradiating laser to the interface between the growth substrate 930 and the upper semiconductor layer 931 to remove the growth substrate 930 and expose the upper surface 9311S2 of the upper semiconductor layer 931.

As shown in FIG. 33D, an upper electrode 97 is formed on the upper surface 9311S2 of the upper semiconductor layer 931. The material and structure of the upper electrode 97 can be referred to the relevant paragraphs of the upper electrode 51, 61, 71. As shown in FIG. 33E, the upper electrode 97, the upper semiconductor layer 931, and the insulating protective layer 96 are pattered by an etching process to form the platforms 931B and 931C and expose the adhesive layer 1E. Besides, a through hole 93T is formed in the platform 931C and penetrates the upper semiconductor layer 931 to expose the bottom electrode 92′.

As shown in FIG. 33F, a conductive portion 98 is formed in the through hole 93T of the platform 931C to connect the bottom electrode 92′, and then a metal electrode 97B is formed on the upper electrode 97 of the platforms 931B and 931C respectively to directly contact the upper electrode 97, wherein the metal electrode 97B is connected to the conductive portion 98 in the platform 931C. In another embodiment, the metal electrode 97B and the conductive portion 98 are formed in the same step.

As shown in FIG. 33G, a portion of the adhesive layer 1E located between platforms 931B and 931C is removed. In details, portions of the adhesive layer 1E and the insulating protective layer 96 uncovered by the platforms 931B and 931C shown in FIGS. 33F and 33G are removed to expose the temporary carrier 930A, and a plurality of adhesive layers 1E′ is discretely distributed and formed respectively to support and adhere the chips 9B′ and 9C′ on the temporary carrier 930A. In one embodiment, the removal process is an etching process, such as an Inductively Coupled Plasma (ICP) etching process.

As shown in FIG. 33H, the chips 9B′ and 9C′ shown in FIG. 33G are transferred from the temporary carrier 930A to the temporary carrier 930B by a transfer process, wherein the chips 9B′ and 9C′ are respectively fixed on the temporary carrier 930B through a plurality of adhesive layers 1F laterally separated from each other. The metal electrodes 97B of the chips 9B′ and 9C′ face the temporary carrier 930B, and the electrical connection portions 95 are formed on the lower electrode 92 of the chip 9B′ and the bottom electrode 92′ of the chip 9C′, respectively. After the above processing, the chips 9B′ and 9C′ are transformed into the chips 9B and 9C respectively. In one embodiment, the transfer process includes forming an adhesive layer 1F to fix the chips 9B′ and 9C′ on the temporary carrier 930B and removing the adhesive layer 1E′, wherein the material and manufacturing process of the adhesive layer 1F can be referred to the relevant paragraphs of the adhesive layer 1E′. The method for removing the adhesive layer 1E′ includes a laser beam irradiation. In one embodiment, the materials of the temporary carriers 930A and 930B can be referred to the relevant paragraphs of the temporary carrier 800 mentioned above.

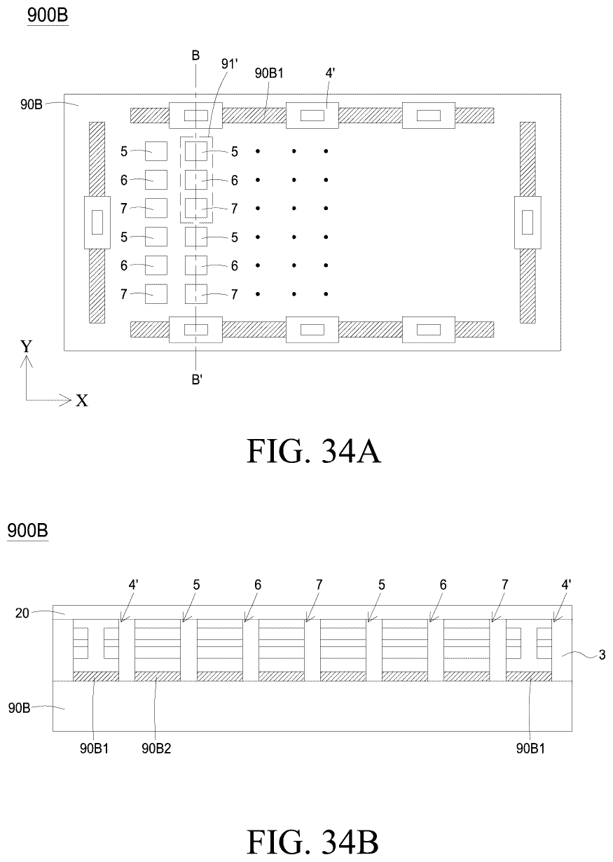

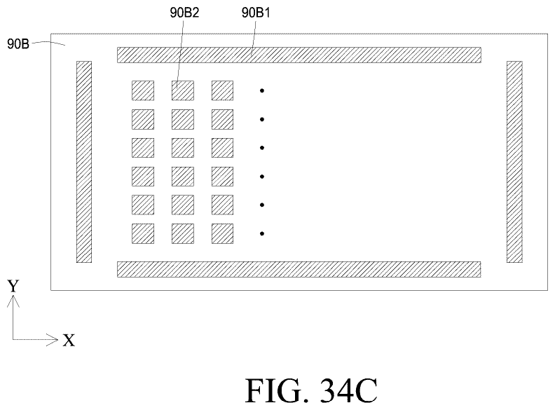

FIGS. 34A to 34C show multiple schematic structural diagrams of a display device 900B according to an embodiment. FIG. 34A shows a top view of the display device 900B, FIG. 34B shows a cross-sectional view along the dotted line BB′ in FIG. 34A, and FIG. 34C shows a top view of a circuit arrangement 90B of the display device 900B. For clarity, the common conductive layer 20, the dielectric layer 3, and part of the common conductive structures 4′ are omitted in FIG. 34A. As shown in FIG. 34A, the display device 900B includes a circuit arrangement 90B, and a plurality of first chips 5, a plurality of second chips 6, and a plurality of third chips 7 are arranged in an array on the circuit arrangement 90B. A plurality of common conductive structures 4′ is set on the circuit arrangement 90B along an edge of the circuit arrangement 90B. The adjacent first chip 5, second chip 6, and third chip 7 can be formed as a pixel 91′. As shown in FIG. 34B, the display device 900B includes a dielectric layer 3 and a common conductive layer 20, wherein the dielectric layer 3 laterally surrounds the common conductive structure 4′, the first chip 5, the second chip 6, and the third chip 7. The common conductive layer 20 directly or indirectly contacts the common conductive structure 4′, the first chip 5, the second chip 6, and the third chip 7, and includes a light-transmissive conductive layer or a light-transmissive carrier with metal mesh (not shown). The material and structure of the light-transmissive conductive layer can be referred to the relevant paragraphs of the light-transmissive conductive layer 2. As shown in FIG. 34C, the circuit arrangement 90B has a plurality of common electrodes 90B1 arranged along the edge of the circuit arrangement 90B, a plurality of lower electrodes 90B2 is arranged in an array on the circuit arrangement 90B. As shown in FIG. 34B, a plurality of common conductive structures 4′ is disposed on and electrically connected to the common electrode 90B1. The plurality of first chips 5, the plurality of second chips 6, and the plurality of third chips 7 are respectively provided on and electrically connected to the plurality of lower electrodes 90B2. In one embodiment, the circuit arrangement 90B is a printed circuit board (PCB), a glass circuit board, a pixel driver IC, or a metal oxide semiconductor (CMOS) circuit element. The first chip 5, the second chip 6, and the third chip 7 can be the chip 9A or 9B, and the common conductive structure 4′ can be the chip 9C or 9C′. In one embodiment, the common conductive structure 4′ is located between and connecting the common conductive layer 20 and the common electrode 90B1 to conduct the current between the common conductive layer 20 and the common electrode 90B1. The first chip 5 is located between and electrically connected to the common conductive layer 20 and the lower electrode 90B2. The second chip 6 is located between and electrically connected to the common conductive layer 20 and the lower electrode 90B2. The third chip 7 is located between and electrically connected to the common conductive layer 20 and the lower electrode 90B2. The first chip 5 can be driven to emit the first light, the second chip 6 can be driven to emit the second light, and the third chip 7 can be driven to emit the third light, wherein the first light, the second light, and the third light can be visible lights with same or different wavelength ranges, or be invisible lights with same wavelength range. Visible lights with the same wavelength range can be a blue light, visible lights with different wavelength ranges can be a red light, a blue light, and a green light, and invisible lights with the same wavelength range can be an ultraviolet light. In order to isolate external mechanical impact and improve the reliability of the display device 900B, the dielectric layer 3 laterally surrounds the common conductive structure 4′, the first chip 5, the second chip 6, and the third chip 7, and is in contact or indirect contact (not shown) with the common conductive layer 20.

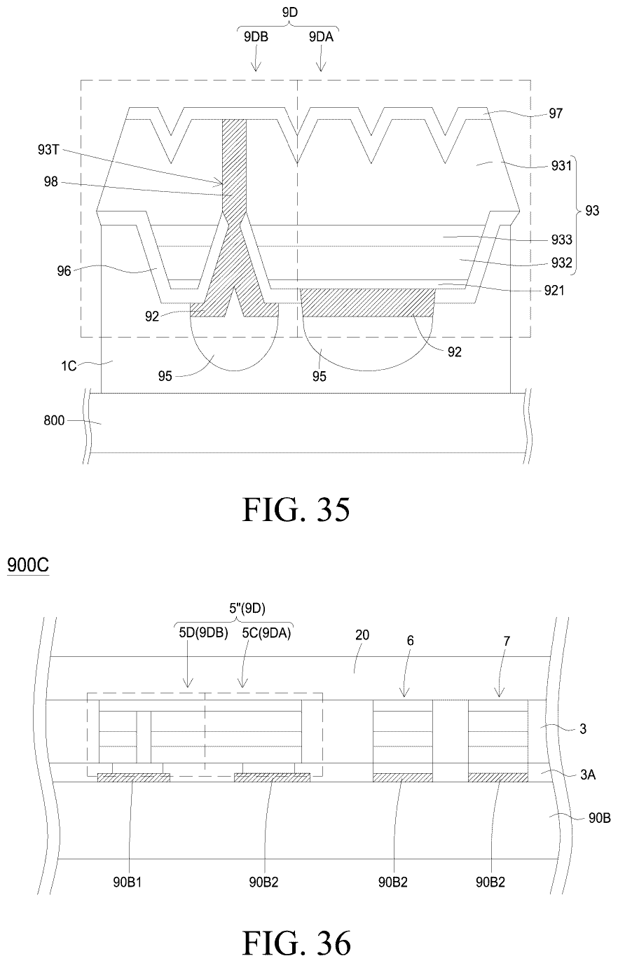

FIG. 35 shows a cross-sectional view of a chip 9D temporarily fixed to a temporary carrier 800 using an adhesive layer 1C according to one embodiment, wherein the materials of the adhesive layer 1C and the temporary carrier 800 can be referred to FIG. 24 and related paragraphs. In another embodiment, the adhesive layer 1C can be replaced by the dual adhesion layer structure 1CD shown in FIG. 25. The chip 9D includes a light-emitting region 9DA and a conductive region 9DB. The light-emitting region 9DA can emit lights, wherein the structure of the light-emitting region 9DA can be referred to the chip 9A in FIG. 22 and related paragraphs. The conductive region 9DB conducts the current but does not emit light, wherein the structure of the conductive region 9DB can be referred to the chip 9C shown in FIG. 32A and related paragraphs. Compared with the chip 9C shown in FIG. 32A, the conductive region 9DB does not have the metal electrode 97B. In another embodiment, the structure of the conductive region 9DB is the same as the structure of the chip 9C shown in FIG. 32A. In one embodiment, the light-emitting region 9DA and the conductive region 9DB of the chip 9D share the ohmic contact layer 921, the semiconductor stack 93, and the upper electrode 97. When the current flows through the upper electrode 97 and the lower electrode 92, the chip 9D emits light. When the current flows through the upper electrode 97 and the bottom electrode 92′, the current flows through the conductive portion 98 so that the chip 9D does not emit light. In one embodiment, the chip 9D has two electrical connection portions 95 that are electrically connected or directly connected to the lower electrode 92 of the light-emitting region 9DA and the bottom electrode 92′ of the conductive region 9DB respectively. In another embodiment, the chip 9D does not has two electrical connection portions 95 and the lower electrode 92 and the bottom electrode 92′ are exposed.

FIG. 36 shows a cross-sectional view of a display device 900C according to an embodiment. The display device 900C is suitable for a small display with a pixel density higher than 1000 Pixels Per Inch (PPI), such as a display for an augmented reality (AR) device. The display device 900C has a dielectric layer 3A between the dielectric layer 3 and circuit arrangement 90B. The dielectric layer 3A includes a black material, such as carbon black, so that the light transmittance of the dielectric layer 3A is less than 20% to cover the metal circuit of the circuit arrangement 90B to improve the contrast of the display device 900C. A first chip 5″ includes a light-emitting region 5C and a conductive region 5D. In one embodiment, the structure of the first chip 5″ can be referred to the chip 9D shown in FIG. 35, wherein the structure of the light-emitting region 5C can be referred to the light-emitting region 9DA of the chip 9D, and the structure of the conductive region 5D can be referred to the conductive region 9DB of the chip 9D. The conductive region 5D is located between and connected to the common conductive layer 20 and the common electrode 90B1 to conduct current between the common conductive layer 20 and the common electrode 90B1. The light-emitting region 5C is located between and connected to the common conductive layer 20 and the lower electrode 90B2 to emit light. In one embodiment, the upper electrode 97 of the chip 9D is electrically connected to common conductive layer 20 (not shown), and the bottom electrode 92′ and the lower electrodes 92 are electrically connected to the common electrode 90B1 and the lower electrode 90B2, respectively. In one embodiment, the circuit arrangement 90B allows the current to flow from the common electrode 90B1 into the common conductive layer 20 through the conductive region 5D of the chip 9D, and allows the current to selectively flow through the light-emitting region 5C, the second chip 6, and/or the third chip 7 by the lower electrode 90B2 of circuit arrangement 90B. Thereby, the light-emitting region 5C, the second chip 6, and/or the third chip 7 can be activated to emit light.

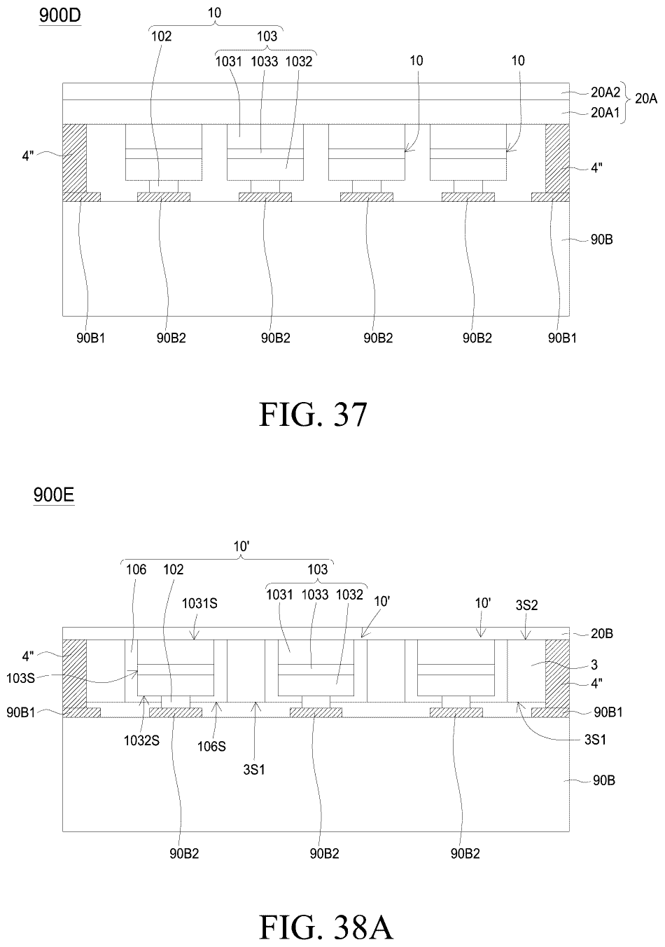

FIG. 37 shows a schematic structural diagram of a light-emitting array device 900D according to an embodiment, wherein the light-emitting array device 900D is suitable for displays or light-emitting devices with a density of light-emitting elements higher than 1000 (pieces/square inch), such as Augmented Reality (AR) displays, Adaptive Driving Beam Headlamp (ADB Headlamp), or light emission modules used in Silicon Photonics (SiPh). The light-emitting array device 900D includes a circuit arrangement 90B having a plurality of common electrodes 90B1 and a plurality of lower electrodes 90B2, a plurality of light-emitting elements 10 located on the circuit arrangement 90B and electrically connected to the plurality of lower electrodes 90B2 respectively, a plurality of common conductive structures 4″ located on the circuit arrangement 90B and electrically connected to the plurality of common electrodes 90B1 respectively, and a common conductive layer 20A located on the plurality of light-emitting elements 10 and the plurality of common conductive structures 4″ and electrically connected to the plurality of light-emitting elements 10 and the plurality of common conductive structures 4″. In one embodiment, the common conductive structure 4″ is located between and connected the common conductive layer 20A and the common electrodes 90B1 to conduct current between the common conductive layer 20A and the common electrodes 90B1. The circuit arrangement 90B allows the current to flow from the common electrode 90B1 into the common conductive layer 20A through the common conductive structure 4″, and allows the current to selectively flow through the light-emitting elements 10 by the lower electrode 90B2 to emit light.

As shown in FIG. 37, one light-emitting element 10 includes a semiconductor stack 103 and a lower electrode 102 connected to the semiconductor stack 103. The lower electrode 102 is electrically connected to the lower electrode 90B2 and is used to conduct the current into the light-emitting element 10. The semiconductor stack 103 includes an upper semiconductor layer 1031, a lower semiconductor layer 1032, and a light-emitting layer 1033. The materials and structures of the semiconductor stack 103, the upper semiconductor layer 1031, the lower semiconductor layer 1032, and the light-emitting layer 1033 can be referred to the relevant paragraphs of the first semiconductor stack 53, the first upper semiconductor layer 531, the first lower semiconductor layer 532, and the first light-emitting layer 533. In an embodiment, the common conductive structure 4″ can be the common conductive structure 4, the common conductive structure 4′, or metal conductive pillars. The metal conductive pillars include a metal single layer or a metal stack, wherein the metal single layer can be a single layer composed of one of chromium, nickel, gold, silver, copper, tin, indium, tungsten, titanium or an alloy of the above materials, the metal stack can be a laminated structure composed of at least two metals selected from chromium, nickel, gold, silver, copper, tin, indium, tungsten, and titanium. In one embodiment, the material of the common conductive layer 20A includes gallium nitride (GaN) based material. As shown in FIG. 37, the common conductive layer 20A includes a first epitaxial layer 20A1 and a second epitaxial layer 20A2. In one embodiment, the first epitaxial layer 20A1 includes n-type gallium nitride (GaN), and the second epitaxial layer 20A2 includes undoped gallium nitride (GaN).

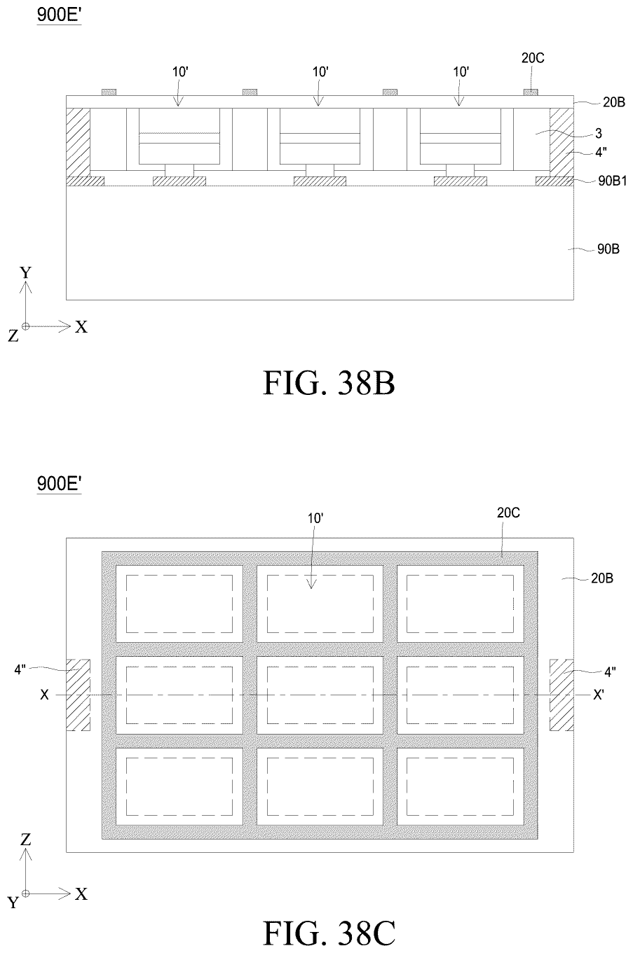

FIG. 38A shows a cross-sectional view of a light-emitting array device 900E according to an embodiment. The light-emitting array device 900E includes a circuit arrangement 90B, a plurality of light-emitting elements 10′, a plurality of common conductive structures 4″, a common conductive layer 20B, and a dielectric layer 3. The circuit arrangement 90B includes a plurality of common electrodes 90B1 and a plurality of lower electrodes 90B2. The plurality of light-emitting elements 10′ is located on the circuit arrangement 90B and are electrically connected to the plurality of lower electrodes 90B2 respectively. The plurality of common conductive structures 4″ is located on the circuit arrangement 90B and are electrically connected to the plurality of common electrodes 90B1 respectively. The common conductive layer 20B is disposed on and electrically connected to the plurality of light-emitting elements 10′ and the plurality of common conductive structures 4″. The dielectric layer 3 surrounds sides of the plurality of light-emitting elements 10′ and directly contacts the common conductive layer 20B.

As shown in FIG. 38A, in one embodiment, the light-emitting element 10′ further includes an insulating protective layer 106 covering the sidewall 103S and the surface 1032S of the semiconductor stack 103, contacting the lower electrode 102 and exposing the surface 1031S. The material and function of the insulating protective layer 106 can be referred to the paragraphs related to the insulating protective layer 96.

As shown in FIG. 38A, the dielectric layer 3 surrounds the light-emitting elements 10′ and directly contacts the insulating protective layer 106. The dielectric layer 3 has a lower surface 3S1 coplanar with the surface 106S of the insulating protective layer 106, and an upper surface 3S2 coplanar with the surface 1031S of the semiconductor stack 103 and in contact with the common conductive layer 20B. The dielectric layer 3 isolates moisture and supports the plurality of light-emitting elements 10′. In one embodiment, the transmittance of the dielectric layer 3 to the light emitted by the light-emitting element 10′ is greater than 70%. The material of the dielectric layer 3 includes a heat-resistant glue, such as BCB (Benzocyclobutene), epoxy or silicone. In another embodiment, the dielectric layer 3 further includes a reflective material (not shown), such as titanium oxide (TiOₓ), or a Distributed Bragg Reflector (DBR) structure, to reflect the light emitted by the light-emitting elements 10′. In one embodiment, the common conductive structure 4″ is located between and connected the common conductive layer 20B and the common electrode 90B1 to conduct the current between the common conductive layer 20B and the common electrode 90B1. The circuit arrangement 90B allows the current to flow from the common electrode 90B1 into common conductive layer 20B through the common conductive structure 4″, and allows the current to flow through the light-emitting elements 10′ by the lower electrode 90B2 to emit light.

As shown in FIG. 38A, in an embodiment, the common conductive structure 4″ can be the common conductive structure 4, the common conductive structure 4′, or metal conductive pillars mentioned above, wherein the metal conductive pillars include a metal single layer or a metal stack. The metal single layer can be a single layer composed of one of chromium, nickel, gold, silver, copper, tin, indium, tungsten, titanium, or an alloy of the above materials, the metal stack can be a laminated structure composed of at least two metals selected from chromium, nickel, gold, silver, copper, tin, indium, tungsten, and titanium. In one embodiment, the material and function of the common conductive layer 20B can be referred to the aforementioned paragraphs related to the light-transmissive conductive layer 2.

FIG. 38B shows a cross-sectional view of a light-emitting array device 900E′ according to an embodiment, and FIG. 38C shows a top view of the light-emitting array device 900E′, wherein FIG. 38B is a cross-sectional view along the dotted line XX′ in FIG. 38C. As shown in FIG. 38B, compared with the light-emitting array device 900E shown in FIG. 38B, the light-emitting array device 900E′ further includes a metal mesh 20C in contact with the common conductive layer 20B. As shown in FIG. 38B, in the Y direction, the metal mesh 20C and the plurality of light-emitting elements 10′ are respectively located on opposite sides of the common conductive layer 20B and do not overlap each other; in the X direction, the metal mesh 20C is interleaved with the plurality of light-emitting elements 10′. As shown in FIG. 38C, the metal mesh 20C is an integrated metal wire and does not cover the plurality of light-emitting elements 10′. The material of the metal mesh 20C includes copper, tin, aluminum, silver, palladium, gold, alloys of the above materials, or stacks of the above materials. The metal mesh 20C can improve the ability of the current to be conducted laterally in the common conductive layer 20B.

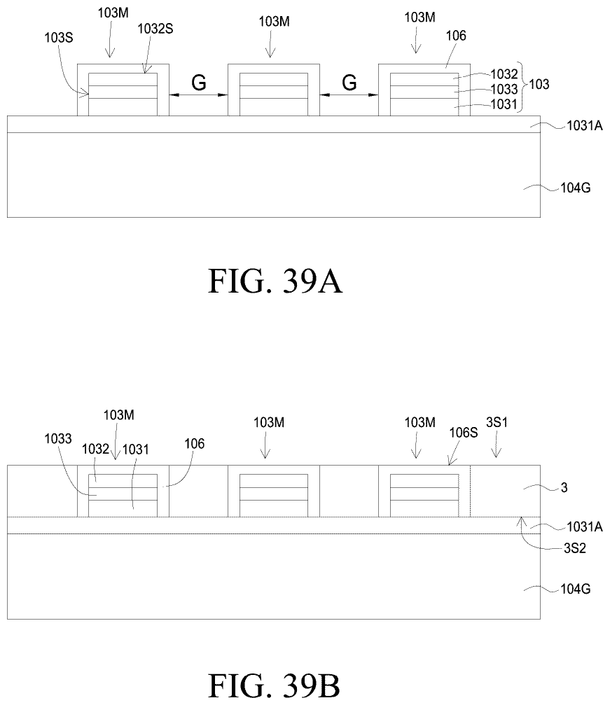

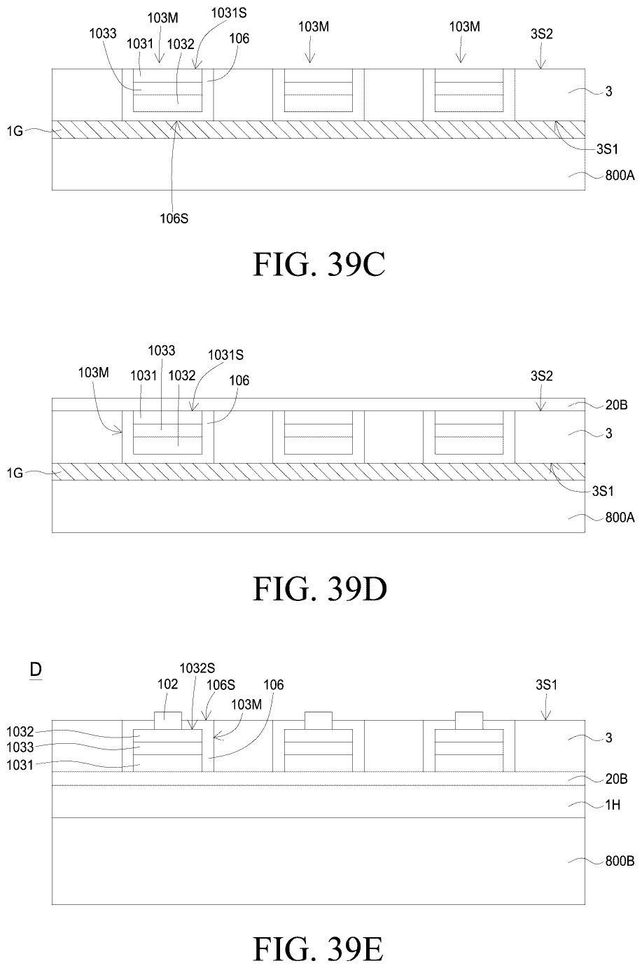

FIGS. 39A to 39E show a manufacturing process of a light-emitting array device 900E according to an embodiment. As shown in FIG. 39A, a growth substrate 104G is provided. An epitaxial layer 1031A is formed on the growth substrate 104G, and a plurality of mesa structures 103M is formed on the epitaxial layer 1031A. The detail description of the growth substrate 104G can be referred to the growth substrate 930 in FIG. 33A and related paragraphs. In one embodiment, the epitaxial layer 1031A includes undoped gallium nitride (GaN), the mesa structures 103M include a semiconductor stack 103 and an insulating protective layer 106 covering the sidewall 103S and surface 1032S of the semiconductor stack 103. The semiconductor stack 103 includes an upper semiconductor layer 1031 contacting the epitaxial layer 1031A, a lower semiconductor layer 1032, and a light-emitting layer 1033 located between the upper semiconductor layer 1031 and the lower semiconductor layer 1032. The material of the upper semiconductor layer 1031 includes n-type gallium nitride (GaN), and the material of the lower semiconductor layer 1032 includes p-type gallium nitride (GaN). The light-emitting layer 1033 includes an MQW structure for emitting light. In one embodiment, two adjacent mesa structures 103M have a constant gap G.

Then, as shown in FIG. 39B, a dielectric layer 3 is formed on the epitaxial layer 1031A and between the adjacent mesa structures 103M through a process such as spin coating, injecting, transfer molding, or compression molding. In one embodiment, the dielectric layer 3 has an upper surface 3S2 in contact with the epitaxial layer 1031A and a lower surface 3S1 coplanar with the surface 106S of the insulating protective layer 106 in the mesa structure 103M.

As shown in FIG. 39C, the mesa structures 103M and the dielectric layer 3 are transferred to the temporary carrier 800A, and the growth substrate 104G and the epitaxial layer 1031A are removed by at least one of processes such as laser lift-off, polishing, and etching, to expose the surface 1031S of the upper semiconductor layer 1031 in the mesa structure 103M and the upper surface 3S2 of the dielectric layer 3. The mesa structure 103M and the dielectric layer 3 are fixed on the temporary carrier 800A through an adhesive layer 1G, wherein the material and manufacturing process of the adhesive layer 1G can be referred to the relevant paragraphs of the adhesive layer 1C or 1D.

As shown in FIG. 39D, a common conductive layer 20B is formed on the surface 1031S of the upper semiconductor layer 1031 of the mesa structures 103M and on the upper surface 3S2 of the dielectric layer 3. The material and manufacturing process of the common conductive layer 20B can be referred to the light-transmissive conductive layer 2.

As shown in FIG. 39E, the plurality of mesa structures 103M, the dielectric layer 3, and common conductive layer 20B are transferred to the temporary carrier 800B, and the adhesive layer 1G is removed or the adhesion of the adhesive layer 1G is reduced by at least one of processes such as laser lift-off, heating, and etching to remove the temporary carrier 800A and expose the surface 106S of the mesa structure 103M and the lower surface 3S1 of the dielectric layer 3. An adhesive layer 1H is formed between the common conductive layer 20B and the temporary carrier 800B. The plurality of mesa structures 103M, the dielectric layer 3, and the common conductive layer 20B are fixed on the temporary carrier 800B through the adhesive layer 1H. The material and manufacturing process of the adhesive layer 1H can be the same or different from those of the adhesive layer 1G. Next, a though hole is formed on the surface 106S of the insulating protective layer 106 to expose a part of the surface 1032S of the lower semiconductor layer 1032, and the lower electrode 102 is formed in the through hole by electroplating or chemical deposition to form a temporary structure D. The material and structure of the lower electrode 102 can be referred to the relevant paragraphs of the lower electrode 52, 62 and 72.

Then, a plurality of common conductive structures 4″ is formed in the dielectric layer 3 of the temporary structure D and connected to the common conductive layer 20B. The lower electrode 102 and the common conductive structure 4″ are electrically connected to the lower electrode 90B2 of the circuit arrangement 90B in FIG. 38A through an alignment welding process to form the light-emitting array device 900E shown in FIG. 38A.

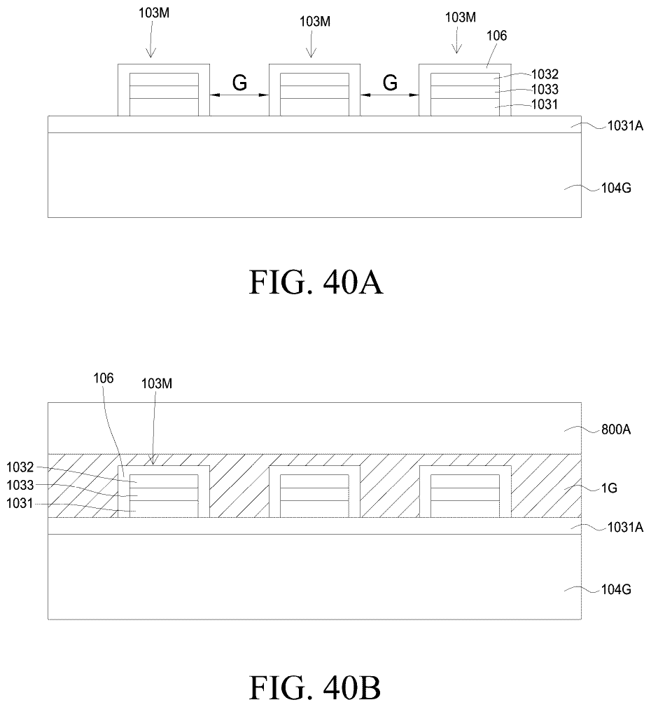

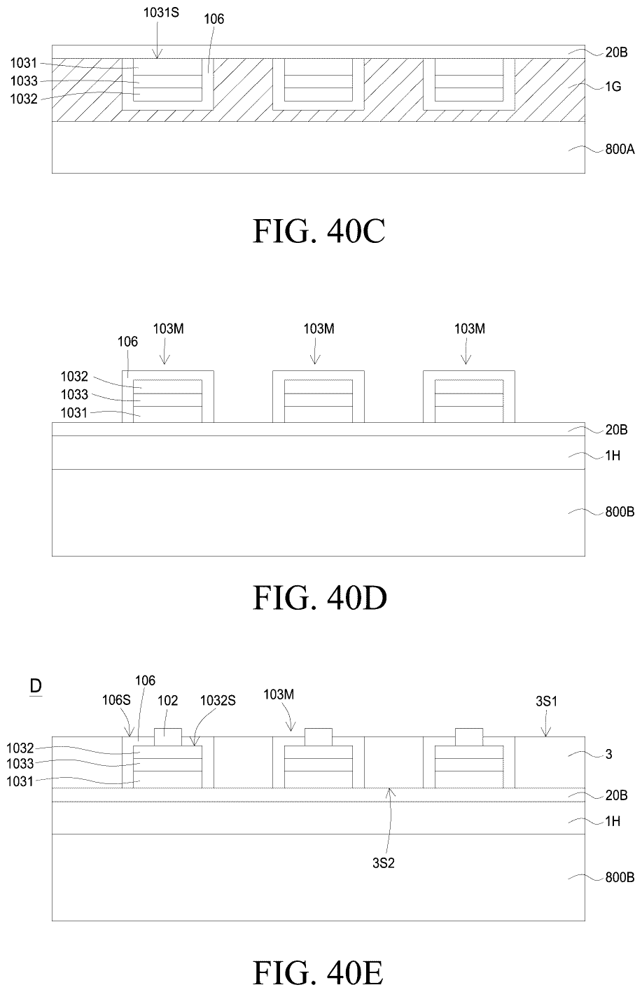

FIGS. 40A to 40E show a manufacturing process of the light-emitting array device 900E according to an embodiment, wherein the manufacturing process of FIG. 40A can be referred to FIG. 39A and the relevant paragraphs.

As shown in FIG. 40B, an adhesive layer 1G is formed through processes such as spin coating, injection, transfer molding, or compression molding to cover the plurality of mesa structures 103M. Then, a temporary carrier 800A is provided and fixed on the adhesive layer 1G. The detailed description of the adhesive layer 1G and the temporary carrier 800A can be referred to the above-mentioned relevant paragraphs.

As shown in FIG. 40C, the growth substrate 104G and the epitaxial layer 1031A are removed using at least one of processes such as laser lift-off, polishing, and etching to expose the surface 1031S of the upper semiconductor layer 1031 in the mesa structure 103M and the adhesive layer 1G. A common conductive layer 20B is formed on the surface 1031S of the mesa structure 103M and the adhesive layer 1G. The material and manufacturing process of the common conductive layer 20B can be referred to the light-transmissive conductive layer 2 as mentioned above.

As shown in FIG. 40D, a temporary carrier 800B is provided and fixed on the common conductive layer 20B through the adhesive layer 1H. The detailed description of the adhesive layer 1H and the temporary carrier 800B can be referred to the above-mentioned relevant paragraphs. The adhesive layer 1G is removed through at least one of laser debonding, heating, and etching processes to expose the common conductive layer 20B and the mesa structure 103M.

As shown in FIG. 40E, the dielectric layer 3 is formed on the common conductive layer 20B and in the space between the two adjacent mesa structures 103M. In one embodiment, the dielectric layer 3 has an upper surface 3S2 in contact with the common conductive layer 20B and a lower surface 3S1 coplanar with the surface 106S of the insulating protective layer 106 in the mesa structure 103M. Next, a through hole is formed on the surface 106S of the insulating protective layer 106 of the mesa structure 103M to expose the surface 1032S of the lower semiconductor layer 1032. The lower electrode 102 is formed in the through hole by electroplating or chemical deposition to form the temporary structure D.

Subsequently, a plurality of common conductive structures 4″ can be formed in the dielectric layer 3 of the temporary structure D and connected to the common conductive layer 20B. The lower electrode 102 and the common conductive structure 4″ are electrically connected to the lower electrode 90B2 of the circuit arrangement 90B in FIG. 38A through an alignment welding process, to form the light-emitting array device 900E.

### REFERENCE SIGNS LIST

1, 1′ light-transmissive carrier; 103S sidewall;
10, 10′ light-emitting element; 104G growth substrate;
100, 100′ pixel structure; 106 insulating protective layer;
1000 support substrate; 106S surface;
1000G adhesive layer 11 surface;
102 lower electrode; 1A temporary carrier;
103 semiconductor stack; 1B, 1C, 1D, 1C′, 1D′, 1E, 1E′, 1F, 1G, 1H
1031 upper semiconductor layer; adhesive layer;
1031A epitaxial layer; 1CD dual adhesion layer structure;
1031S surface; 2, 2′ light-transmissive conductive layer;
1032 lower semiconductor layer; 20, 20A,20B common conductive layer;
1032S surface; 200 pixel structure;
1033 light-emitting layer; 20A1 first epitaxial layer;
103M mesa structure; 20A2 second epitaxial layer;
20C metal mesh; 523 metal connection layer;
3, 3′, 3A dielectric layer; 53 first semiconductor stack;
31 first common surface; 531, 531′ first upper semiconductor layer;
32 second common surface; 532, 532A, 532B first lower
3S1 lower surface; semiconductor layer;
3S2 upper surface; 533, 533A first light-emitting layer;
4, 4′, 4″ common conductive structure; 533B MQW structure;
400 temporary carrier; 53A light-emitting stack region;
41 top electrode; 53B conductive stack region;
42 bottom electrode; 54 insulating layer;
43 semiconductor structure; 55 through hole;
431 upper semiconductor layer; 5A, 5C light-emitting region;
432 lower semiconductor layer; 5B, 5D conductive region;
433 MQW structure; 6 second chip;
43S1 first sidewall; 600 temporary carrier;
43S2 second sidewall; 61 upper electrode;
44, 44′ conductive portion; 611 light-transmissive conductive layer;
5, 5′, 5″ first chip; 612 current channel layer;
500 temporary carrier; 62 lower electrode;
51, 51′ upper electrode; 621 reflective metal layer;
511 light-transmissive conductive layer; 622 barrier metal layer;
512 current channel layer; 623 metal connection layer;
52, 52A, 52B lower electrode; 63 second semiconductor stack;
521 reflective metal layer; 631 second upper semiconductor layer;
522 barrier metal layer; 632 second lower semiconductor layer;
633 second light-emitting layer; 90B1 common electrode;
7 third chip; 90B2 lower electrode;
700 temporary carrier; 900A, 900B, 900C display device;
71 upper electrode; 900D, 900E, 900E′ light-emitting array
711 light-transmissive conductive layer; device;
712 current channel layer; 91, 91′ pixel;
72 lower electrode; 92 lower electrode;
721 reflective metal layer; 92′ bottom electrode;
722 barrier metal layer; 921 ohmic contact layer;
723 metal connection layer; 92T recessed portion;
73 third semiconductor stack; 93 semiconductor stack;
731 third upper semiconductor layer; 930 growth substrate;
732 third lower semiconductor layer; 930A, 930B temporary carrier;
733 third light-emitting layer; 930S patterned surface;
8 circuit redistribution layer; 931 upper semiconductor layer;
800, 800′, 800A, 800B temporary carrier; 9311 first upper semiconductor layer;
800S, 800AS surface; 9311S1 middle side surface;
81 common bonding pad; 9311S2 upper surface;
82 first bonding pad; 9312 second upper semiconductor layer;
83 second bonding pad; 931B, 931C platform;
84 third bonding pad; 932 lower semiconductor layer;
8A lower surface; 932S lower surface;
8B upper surface; 933 MQW structure;
90 circuit board; 93B, 93C platform;
90B circuit arrangement; 93S side surface;
93S1 upper side surface; AA′, BB′, XX′ dotted line;
93S2 lower side surface; θ1, θ2 included angle
93T through hole;
93V groove;
95 electrical connection portion;
95-1 first electrical connection portion;
95-2 second electrical connection portion;
96 insulating protective layer;
97 upper electrode;
97B metal electrode;
98 conductive portion;
99 dotted line;
9A, 9B, 9B′, 9C, 9C′, 9D chip;
9Aa, 9Da front side;
9Ab, 9Db back side;
9DA light-emitting region;
9DB conductive region;
A, B, C arrangement structure;
D temporary structure;
G gap;
H1, H4, H5, H6, H7 height;
T1 first temperature;
Tg glass transition temperature;
W1 side length;
W1C, W9A, W9D width;

1. A pixel structure, comprising:
a first chip, used for emitting a first light, comprising a first semiconductor stack, a first upper electrode located above the first semiconductor stack, and a first lower electrode located below the first semiconductor stack;
a second chip, used for emitting a second light, comprising a second semiconductor stack, a second upper electrode located above the second semiconductor stack, and a second lower electrode located below the second semiconductor stack;
a common conductive structure, comprising a semiconductor structure, an top electrode located above the semiconductor structure, a bottom electrode located below the semiconductor structure, and a conductive portion located between the top electrode and the bottom electrode;
a dielectric layer, surrounding and contacting the first chip, the second chip, and the common conductive structure; and
a light-transmissive conductive layer, covering and electrical connecting the first upper electrode, the second upper electrode, and the top electrode;
wherein the semiconductor structure and the first semiconductor stack have the same material, and the semiconductor structure do not emit light when a current flow through therein.

2. The pixel structure according to claim 1, further comprising a light-transmissive carrier covering the light-transmissive conductive layer.

3. The pixel structure according to claim 1, wherein the semiconductor structure has a sidewall located between the top electrode and the bottom electrode, and the conductive portion directly contacts the sidewall.

4. The pixel structure according to claim 1, wherein the conductive portion is located in the semiconductor structure.

5. The pixel structure according to claim 1, wherein the first light and the second light have different peak wavelengths.

6. The pixel structure according to claim 1, wherein the light-transmissive conductive layer is directly connected the first upper electrode, the second upper electrode, and the top electrode.

7. The pixel structure according to claim 1, further comprising a plurality of pads connected to the first lower electrode, the second lower electrode, and the bottom electrode, respectively.

8. The pixel structure according to claim 1, wherein the first semiconductor stack comprises Nitrogen (N), and the second semiconductor stack comprises Arsenic (As).

9. The pixel structure according to claim 1, wherein the first semiconductor stack comprises a first upper semiconductor layer, and the semiconductor structure and the first semiconductor stack share the first upper semiconductor layer.

10. The pixel structure according to claim 1, further comprising a third chip used for emitting a third light, wherein the first light, the second light, and the third light are red, blue, and green light, respectively.
